(19) United States
(12) Patent Application Publication
(10) Pub. No.: US 2002/0036328 A1
(43) Pub. Date: Mar. 28, 2002

(54) OFFSET DRAIN FERMI-THRESHOLD FIELD EFFECT TRANSISTORS

(76) Inventors: WILLIAM R. RICHARDS, JR., CARY, NC (US); MICHAEL W. DENNEN, RALEIGH, NC (US)

Correspondence Address: MYERS BIGEL SIBLEY & SAJOVEC, PO BOX 37428, RALEIGH, NC, 27627, US

(21) Appl. No.: 09/192,952

(22) Filed: Nov. 16, 1998

(51) Int. Cl. H01L 29/76

(52) U.S. Cl. 257/401; 257/386; 257/327; 257/339

(57) ABSTRACT

An offset drain Fermi-threshold field effect transistor (Fermi-FET) includes spaced apart source and drain regions in an integrated circuit substrate, and a Fermi-FET channel in the integrated circuit substrate, between the spaced apart source and drain regions. A gate insulating layer is on the integrated circuit substrate between the spaced apart source and drain regions, and a gate electrode is on the gate insulating layer. The gate electrode is closer to the source region than to the drain region. Stated differently, the drain region is spaced farther away from the gate electrode than the source region. The offset drain Fermi-FET can introduce a drift region between the drain region and the Fermi-FET channel that can provide the high voltage and/or high frequency Fermi-FETs, while retaining the Fermi-FET advantages in the channel.

### FIELD OF THE INVENTION

This invention relates to field effect transistor devices and more particularly to integrated circuit field effect transistors.

### BACKGROUND OF THE INVENTION

Field effect transistors (FET) have become the dominant active device for very large scale integration (VLSI) and ultra large scale integration (ULSI) applications, such as logic devices, memory devices and microprocessors, because the integrated circuit FET is by nature a high impedance, high density, low power device. Much research and development activity has focused on improving the speed and integration density of FETs, and on lowering the power consumption thereof.

A high speed, high performance field effect transistor is described in U.S. Pat. Nos. 4,984,043 and 4,990,974, both by Albert W. Vinal, both entitled Fermi Threshold Field Effect Transistor and both assigned to the assignee of the present invention, the disclosures of which are hereby incorporated herein by reference. These patents describe a metal oxide semiconductor field effect transistor (MOSFET) which operates in the enhancement mode without requiring inversion, by setting the device's threshold voltage to twice the Fermi potential of the semiconductor material. As is well known to those having skill in the art, Fermi potential is defined as that potential for which an energy state in a semiconductor material has a probability of one-half of being occupied by an electron. As described in the above mentioned Vinal patents, when the threshold voltage is set to twice the Fermi potential, the dependence of the threshold voltage on oxide thickness, channel length, drain voltage and substrate doping is substantially eliminated. Moreover, when the threshold voltage is set to twice the Fermi potential, the vertical electric field at the substrate face between the oxide and channel is minimized, and is in fact substantially zero. Carrier mobility in the channel is thereby maximized, leading to a high speed device with greatly reduced hot electron effects. Device performance is substantially independent of device dimensions.

Notwithstanding the vast improvement of the Fermi-threshold FET compared to known FET devices, there was a need to lower the capacitance of the Fermi-FET device. Accordingly, in U.S. Pat. Nos. 5,194,923 and 5,369,295, both by Albert W. Vinal, and both entitled Fermi Threshold Field Effect Transistor With Reduced Gate and Diffusion Capacitance, both assigned to the assignee of the present invention, the disclosures of which are hereby incorporated herein by reference, a Fermi-FET device is described which allows conduction carriers to flow within the channel at a predetermined depth in the substrate below the gate, without requiring an inversion layer to be created at the surface of the semiconductor in order to support carrier conduction. Accordingly, the average depth of the channel charge requires inclusion of the permittivity of the substrate as part of the gate capacitance. Gate capacitance is thereby substantially reduced.

As described in the aforesaid '295 and '923 patents, the low capacitance Fermi-FET is preferably implemented using a Fermi-tub region having a predetermined depth and a conductivity type opposite the substrate and the same conductivity type as the drain and source. The Fermi-tub extends downward from the substrate surface by a predetermined depth, and the drain and source diffusions are formed in the Fermi-tub within the tub boundaries. The Fermi-tub forms a unijunction transistor, in which the source, drain, channel and Fermi-tub are all doped the same conductivity type, but at different doping concentrations. A low capacitance Fermi-FET is thereby provided. The low capacitance Fermi-FET including the Fermi-tub will be referred to herein as a “low capacitance Fermi-FET” or a “Tub-FET”.

Notwithstanding the vast improvement of the Fermi-FET and the low capacitance Fermi-FET compared to known FET devices, there was a continuing need to increase the current per unit channel width which is produced by the Fermi-FET. As is well known to those skilled in the art, higher current Fermi-FET devices will allow greater integration density, and/or much higher speeds for logic devices, memory devices, microprocessors and other integrated circuit devices. Accordingly, U.S. Pat. No. 5,374,836 to Albert W. Vinal and the present coinventor Michael W. Dennen entitled High Current Fermi-Threshold Field Effect Transistor, assigned to the assignee of the present invention, the disclosure of which is hereby incorporated herein by reference, describes a Fermi-FET which includes an injector region of the same conductivity type as the Fermi-tub region and the source region, adjacent the source region and facing the drain region. The injector region is preferably doped at a doping level which is intermediate to the relatively low doping concentration of the Fermi-tub and the relatively high doping concentration of the source. The injector region controls the depth of the carriers injected into the channel and enhances injection of carriers in the channel, at a predetermined depth below the gate. Transistors according to U.S. Pat. No. 5,374,836 will be referred to herein as a “high current Fermi-FET”.

Preferably, the source injector region is a source injector tub region which surrounds the source region. A drain injector tub region may also be provided. A gate sidewall spacer which extends from adjacent the source injector region to adjacent the gate electrode of the Fermi-FET may also be provided in order to lower the pinch-off voltage and increase saturation current for the Fermi-FET. A bottom leakage control region of the same conductivity type as the substrate may also be provided.

Notwithstanding the vast improvement of the Fermi-FET, the low capacitance Fermi-FET and the high current Fermi-FET compared to known FET devices, there was a continuing need to improve operation of the Fermi-FET at low voltages. As is well known to those having skill in the art, there is currently much emphasis on low power portable and/or battery-powered devices which typically operate at power supply voltages of five volts, three volts, one volt or less.

For a given channel length, lowering of the operating voltage causes the lateral electric field to drop linearly. At very low operating voltages, the lateral electric field is so low that the carriers in the channel are prevented from reaching saturation velocity. This results in a precipitous drop in the available drain current. The drop in drain current effectively limits the decrease in operating voltage for obtaining usable circuit speeds for a given channel length.

In order to improve operation of the Tub-FET at low voltages, U.S. Pat. No. 5,543,654 to the present coinventor Michael W. Dennen entitled Contoured-Tub Fermi-Threshold Field Effect Transistor and Method of Forming Same, assigned to the assignee of the present invention, the disclosure of which is hereby incorporated herein by reference, describes a Fermi-FET which includes a contoured Fermi-tub region having nonuniform tub depth. In particular, the Fermi-tub is deeper under the source and/or drain regions than under the channel region. Thus, the tub-substrate junction is deeper under the source and/or drain regions than under the channel region. Diffusion capacitance is thereby reduced compared to a Fermi-tub having a uniform tub depth, so that high saturation current is produced at low voltages.

In particular, a contoured-tub Fermi-threshold field effect transistor according to the '654 patent includes a semiconductor substrate of first conductivity type and spaced-apart source and drain regions of second conductivity type in the semiconductor substrate at a face thereof. A channel region of the second conductivity type is also formed in the semiconductor substrate at the substrate face between the spaced-apart source and drain regions. A tub region of the second conductivity type is also included in the semiconductor substrate at the substrate face. The tub region extends a first predetermined depth from the substrate face to below at least one of the spaced-apart source and drain regions, and extends a second predetermined depth from the substrate face to below the channel region. The second predetermined depth is less than the first predetermined depth. A gate insulating layer and source, drain and gate contacts are also included. A substrate contact may also be included.

Preferably, the second predetermined depth, i.e. the depth of the contoured-tub adjacent the channel, is selected to satisfy the Fermi-FET criteria as defined in the aforementioned U.S. Pat. Nos. 5,194,923 and 5,369,295. In particular, the second predetermined depth is selected to produce zero static electric field perpendicular to the substrate face at the bottom of the channel with the gate electrode at ground potential. The second predetermined depth may also be selected to produce a threshold voltage for the field effect transistor which is twice the Fermi potential of the semiconductor substrate. The first predetermined depth, i.e. the depth of the contoured-tub region adjacent the source and/or drain is preferably selected to deplete the tub region under the source and/or drain regions upon application of zero bias to the source and/or drain contact.

As the state of the art in microelectronic fabrication has progressed, fabrication linewidths have been reduced to substantially less than one micron. These decreased linewidths have given rise to the “short channel” FET wherein the channel length is substantially less than one micron and is generally less than one half micron with current processing technology.

The low capacitance Fermi-FET of Pat. Nos. 5,194,923 and 5,369,295, the high current Fermi-FET of Pat. No. 5,374,836 and the contoured tub Fermi-FET of U.S. Pat. No. 5,543,654 may be used to provide a short channel FET with high performance capabilities at low voltages. However, it will be recognized by those having skill in the art that as linewidths decrease, processing limitations may limit the dimensions and conductivities which are attainable in fabricating an FET. Accordingly, for decreased linewidths, processing conditions may require reoptimization of the Fermi-FET transistor to accommodate these processing limitations.

Reoptimization of the Fermi-FET transistor to accommodate processing limitations was provided in application Ser. No. 08/505,085 to the present coinventor Michael W. Dennen and entitled “Short Channel Fermi-Threshold Field Effect Transistors”, assigned to the assignee of the present invention, the disclosure of which is hereby incorporated herein by reference. The Short Channel Fermi-FET of application Ser. No. 08/505,085, referred to herein as the “short channel Fermi-FET”, includes spaced-apart source and drain regions which extend beyond the Fermi-tub in the depth direction and which may also extend beyond the Fermi-tub in the lateral direction. Since the source and drain regions extend beyond the tub, a junction with the substrate is formed which can lead to a charge-sharing condition. In order to compensate for this condition, the substrate doping is increased. The very small separation between the source and drain regions leads to a desirability to reduce the tub depth. This causes a change in the static electrical field perpendicular to the substrate at the oxide:substrate interface when the gate electrode is at threshold potential. In typical long channel Fermi-FET transistors, this field is essentially zero. In short channel devices the field is significantly lower than a MOSFET transistor, but somewhat higher than a long channel Fermi-FET.

In particular, a short channel Fermi-FET includes a semiconductor substrate of first conductivity type and a tub region of second conductivity type in the substrate at a surface thereof which extends a first depth from the substrate surface. The short channel Fermi-FET also includes spaced-apart source and drain regions of the second conductivity type in the tub region. The spaced-apart source and drain regions extend from the substrate surface to beyond the first depth, and may also extend laterally away from one another to beyond the tub region.

A channel region of the second conductivity type is included in the tub region, between the spaced-apart source and drain regions and extending a second depth from the substrate surface such that the second depth is less than the first depth. At least one of the first and second depths are selected to minimize the static electric field perpendicular to the substrate surface, from the substrate surface to the second depth when the gate electrode is at threshold potential. For example, a static electric field of 10⁴ V/cm may be produced in a short channel Fermi-FET compared to a static electric field of more than 10⁵ V/cm in a conventional MOSFET. In contrast, the Tub-FET of U.S. Pat. Nos. 5,194,923 and 5,369,295 may produce a static electric field of less than (and often considerably less than) 10³ V/cm which is essentially zero when compared to a conventional MOSFET. The first and second depths may also be selected to produce a threshold voltage for the field effect transistor which is twice the Fermi-potential of the semiconductor substrate, and may also be selected to allow carriers of the second conductivity type to flow from the source region to the drain region in the channel region at the second depth upon application of the threshold voltage to the gate electrode, and extending from the second depth toward the substrate surface upon application of voltage to the gate electrode beyond the threshold voltage of the field effect transistor, without creating an inversion layer in the channel. The transistor further includes a gate insulating layer and source, drain and gate contacts. A substrate contact may also be included.

Continued miniaturization of integrated circuit field effect transistors has reduced the channel length to well below one micron. This continued miniaturization of the transistor has often required very high substrate doping levels. High doping levels and the decreased operating voltages which may be required by the smaller devices, may cause a large increase in the capacitance associated with the source and drain regions of both the Fermi-FET and conventional MOSFET devices.

In particular, as the Fermi-FET is scaled to below one micron, it is typically necessary to make the tub depth substantially shallower due to increased Drain Induced Barrier Lowering (DIBL) at the source. Unfortunately, even with the changes described above for the short channel Fermi-FET, the short channel Fermi-FET may reach a size where the depths and doping levels which are desired to control Drain Induced Barrier Lowering and transistor leakage become difficult to manufacture. Moreover, the high doping levels in the channel may reduce carrier mobility which also may reduce the high current advantage of the Fermi-FET technology. The ever higher substrate doping levels, together with the reduced drain voltage may also cause an increase in the junction capacitance.

A short channel Fermi-FET that can overcome these potential problems was provided in U.S. Pat. No. No. 5,698,884 to the present coinventor Michael W. Dennen and entitled “Short Channel Fermi-Threshold Field Effect Transistors Including Drain Field Termination Region and Methods of Fabricating Same” assigned to the assignee of the present invention, the disclosure of which is hereby incorporated herein by reference. This Fermi-FET includes drain field terminating means between the source and drain regions for reducing and preferably preventing injection of carriers from the source region into the channel as a result of drain bias. A short channel Fermi-FET including drain field terminating means, referred to herein as a “Vinal-FET” in memory of the now deceased inventor of the Fermi-FET, prevents excessive Drain Induced Barrier Lowering while still allowing low vertical field in the channel, similar to a Fermi-FET. In addition, the Vinal-FET permits much higher carrier mobility and simultaneously leads to a large reduction in source and drain junction capacitance.

The drain field terminating means is preferably embodied by a buried contra-doped layer between the source and drain regions and extending beneath the substrate surface from the source region to the drain region. In particular, a Vinal-FET includes a semiconductor substrate of first conductivity type and a tub region of second conductivity type in the substrate at a surface thereof. Spaced apart source and drain regions of the second conductivity type are included in the tub region at the substrate surface. A buried drain field terminating region of the first conductivity type is also included in the tub region. The buried drain field terminating region extends beneath the substrate surface from the source region to the drain region. A gate insulating layer and source, drain and gate electrodes are also included. Accordingly, the Vinal-FET may be regarded as a Fermi-FET with an added contra-doped buried drain field terminating region which prevents drain bias from causing carriers to be injected from the source region into the tub region.

As the channel length and integration density of integrated circuit field effect transistors continues to increase, the operating voltages of the transistors has also continued to decrease. This decrease is further motivated by the increasing use of integrated circuits in portable electronic devices, such as laptop computers, cellular telephones, personal digital assistants and the like. As the operating voltage of the field effect transistors decrease, it is also generally desirable to lower the threshold voltage.

Accordingly, in order to provide short channel Fermi-FETs for low voltage operation, it is desirable to reduce the threshold voltage, for example to about half a volt or less. However, this reduction in threshold voltage should not produce performance degradation in other areas of the Fermi-FET. For example, a reduction in threshold voltage should not unduly increase the leakage current of the Fermi-FET, or unduly decrease the saturation current of the Fermi-FET.

A Fermi-FET that can provide short channel, low threshold voltage operation while maintaining high saturation currents and low leakage currents is described in application Ser. No. 08/938,213 entitled “Metal Gate Fermi-Threshold Field Effect Transistors” to the present coinventors Michael W. Dennen and William R. Richards, Jr., assigned to the assignee of the present invention, the disclosure of which is hereby incorporated herein by reference. Described is a Fermi-threshold field effect transistor that includes a metal gate. A contra-doped polysilicon gate is not used directly on the gate insulating layer. The metal gate can lower the threshold voltage of the Fermi-FET without degrading other desirable characteristics of the Fermi-FET.

In modern electronic devices, field effect transistors also are often used for high voltage and/or high frequency applications. For example, field effect transistors are often used in the transceiver portion of a cellular radiotelephone, wherein high voltage and/or high frequency operation is desirable. The Fermi-FET, with its high mobility, high saturation current, low leakage current and/or other desirable characteristics would be a desirable candidate for high voltage and/or high frequency operation.

### SUMMARY OF THE INVENTION

It is therefore an object of the present invention to provide Fermi-threshold Field Effect Transistors (Fermi-FETs) that can be used for high voltage and/or high frequency operation.

This and other objects are provided, according to the present invention, by an offset drain Fermi-threshold field effect transistor. The offset drain Fermi-FET can introduce a drift region between the drain region and the Fermi-FET channel that can improve the high voltage and/or high frequency operation of the Fermi-FET, while retaining the Fermi-FET advantages in the channel. The drift region is preferably doped the same conductivity type as the drain region, and is preferably doped at a lower doping concentration than the drain region but at a higher doping concentration than the channel region.

In particular, Fermi-threshold field effect transistors (Fermi-FETs) according to the present invention include spaced apart source and drain regions in an integrated circuit substrate, and a Fermi-FET channel in the integrated circuit substrate, between the spaced apart source and drain regions. A gate insulating layer is on the integrated circuit substrate, between the spaced apart source and drain regions, and a gate electrode is on the gate insulating layer. The gate electrode is closer to the source region than to the drain region. Stated differently, the drain region is spaced farther away from the gate electrode than the source region. Stated in another alternative manner, the gate electrode includes first and second ends, the source region is adjacent the first end of the gate electrode and the drain region is laterally spaced apart from the second end of the gate electrode. The source region is preferably laterally spaced apart from the first end of the gate electrode by a first distance and the drain region is laterally spaced apart from the second end of the gate electrode by a second distance that is greater than the first distance.

An offset drain Fermi-FET may be embodied as an original Fermi-FET, a Tub-FET, a high current Fermi-FET, a contoured-tub Fermi-FET, a short channel Fermi-FET, a Vinal-FET, a metal gate Fermi-FET or other embodiments of a Fermi-FET. By removing the drain from the gate, a drift region may be created to absorb high drain fields, to thereby provide the high voltage and/or high frequency Fermi-FETs, that can have enhanced performance compared to conventional high voltage and/or high frequency FETs.

### BRIEF DESCRIPTION OF THE DRAWINGS

FIG. 1 illustrates a cross-sectional view of an N-channel high current Fermi-FET according to U.S. Pat. No. No. 5,374,836.

FIG. 2A illustrates a cross-sectional view of a first embodiment of a short channel low leakage current Fermi-FET according to U.S. Pat. No. 5,374,836.

FIG. 2B illustrates a cross-sectional view of a second embodiment of a short channel low leakage current Fermi-FET according to U.S. Pat. No. 5,374,836.

FIG. 3 illustrates a cross-sectional view of an N-channel contoured-tub Fermi-FET according to U.S. Pat. No. No. 5,543,654.

FIG. 4 illustrates a cross-sectional view of an N-channel short channel Fermi-FET according to U.S. Pat. No. No. 5,543,654.

FIG. 5 illustrates a cross-sectional view of a second embodiment of an N-channel short channel Fermi-FET according to application Ser. No. 08/505,085.

FIG. 6 illustrates a cross-sectional view of a first embodiment of a Vinal-FET according to U.S. Pat. No. No. 5,698,884.

FIG. 7 illustrates a cross-sectional view of a second embodiment of a Vinal-FET according to U.S. Pat. No. No. 5,698,884.

FIG. 8 illustrates a cross-sectional view of an embodiment of a metal gate Fermi-FET according to application Ser. No. 08/938,213.

FIG. 9 illustrates a cross-sectional view of a first embodiment of offset drain Fermi-FETs according to the present invention.

FIG. 10 illustrates a cross-sectional view of a second embodiment of offset drain Fermi-FETs according to the present invention.

FIGS. 11-26 graphically illustrate simulation results for an offset drain Fermi-FET according to the present invention.

### DETAILED DESCRIPTION OF PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

Before describing offset drain Fermi-threshold field effect transistors of the present invention, a Fermi-threshold field effect transistor with reduced gate and diffusion capacitance of U.S. Pat. Nos. 5,194,923 and 5,369,295 (also referred to as the “low capacitance Fermi-FET” or the “Tub-FET”) will be described as will a high current Fermi-Threshold field effect transistor of U.S. Pat. No. 5,374,836. A contoured-tub Fermi-FET according to U.S. Pat. No. 5,543,654 will also be described. Short channel Fermi-FETs of application Ser. No. 08/505,085 will also be described. Vinal-FETs of U.S. Pat. No. No. 5,698,884 will also be described. Metal gate Fermi-FETs of application Ser. No. 08/938,213 will also be described. A more complete description may be found in these patents and applications, the disclosures of which are hereby incorporated herein by reference. Offset drain Fermi-FETs according to the present invention will then be described.

Fermi-FET With Reduced Gate and Diffusion Capacitance

The following summarizes the low capacitance Fermi-FET including the Ferni-tub. Additional details may be found in U.S. Pat. Nos. 5,194,923 and 5,369,295.

Conventional MOSFET devices require an inversion layer to be created at the surface of the semiconductor in order to support carrier conduction. The depth of the inversion layer is typically 100 Å or less. Under these circumstances gate capacitance is essentially the permittivity of the gate insulator layer divided by its thickness. In other words, the channel charge is so close to the surface that effects of the dielectric properties of the substrate are insignificant in determining gate capacitance.

Gate capacitance can be lowered if conduction carriers are confined within a channel region below the gate, where the average depth of the channel charge requires inclusion of the permittivity of the substrate to calculate gate capacitance. In general, the gate capacitance of the low capacitance Fermi-FET is described by the following equation:

$${C}_{g} = \frac{1}{\frac{{Y}_{f}}{{βϵ}_{s}} + \frac{{T}_{ox}}{{ϵ}_{i}}} \qquad ( 1 )$$

Where Y_{f} is the depth of the conduction channel called the Fermi channel, εₛ is the permittivity of the substrate, and β is the factor that determines the average depth of the charge flowing within the Fermi channel below the surface. β depends on the depth dependant profile of carriers injected from the source into the channel. For the low capacitance Fermi-FET, β≅2. Tₒₓ is the thickness of the gate oxide layer and εᵢ is its permittivity.

The low capacitance Fermi-FET includes a Fermi-tub region of predetermined depth, having conductivity type opposite the substrate conductivity type and the same conductivity type as the drain and source regions. The Fermi-tub extends downward from the substrate surface by a predetermined depth, and the drain and source diffusions are formed in the Ferni-tub region within the Fermi-tub boundaries. The preferred Fermi-tub depth is the sum of the Fermi channel depth Y_{f} and depletion depth Y₀. A Fermi channel region with predetermined depth Y_{f} and width Z, extends between the source and drain diffusions. The conductivity of the Fermi channel is controlled by the voltage applied to the gate electrode.

The gate capacitance is primarily determined by the depth of the Fermi channel and the carrier distribution in the Fermi channel, and is relatively independent of the thickness of the gate oxide layer. The diffusion capacitance is inversely dependant on the difference between [the sum of the depth of the Fermi-tub and the depletion depth YO in the substrate] and the depth of the diffusions X_{d}. The diffusion depth is preferably less than the depth of the Fermi-tub, Y_{T}. The dopant concentration for the Fermi-tub region is preferably chosen to allow the depth of the Fermi channel to be greater than three times the depth of an inversion layer within a MOSFET.

Accordingly, the low capacitance Fermi-FET includes a semiconductor substrate of first conductivity type having a first surface, a Ferni-tub region of second conductivity type in the substrate at the first surface, spaced apart source and drain regions of the second conductivity type in the Fermi-tub region at the first surface, and a channel of the second conductivity type in the Fermi-tub region at the first surface between the spaced apart source and drain regions. The channel extends a first predetermined depth (Y_{f}) from the first surface and the tub extends a second predetermined depth (Y₀) from the channel. A gate insulating layer is provided on the substrate at the first surface between the spaced apart source and drain regions. Source, drain and gate electrodes are provided for electrically contacting the source and drain regions and the gate insulating layer respectively.

At least the first and second predetermined depths are selected to produce zero static electric field perpendicular to the first surface at the first depth, upon application of the threshold voltage of the field effect transistor to the gate electrode. The first and second predetermined depths are also selected to allow carriers of the second conductivity type to flow from the source to the drain in the channel, extending from the first predetermined depth toward the first surface upon application of the voltage to the gate electrode beyond the threshold voltage of the field effect transistor. The carriers flow from the source to the drain region beneath the first surface without creating an inversion layer in the Fermi-tub region. The first and second predetermined depths are also selected to produce a voltage at the substrate surface, adjacent the gate insulating layer, which is equal and opposite to the sum of the voltages between the substrate contact and the substrate and between the polysilicon gate electrode and the gate electrode.

When the substrate is doped at a doping density Nₛ, has an intrinsic carrier concentration nᵢ at temperature T degrees Kelvin and a permittivity εₛ, and the field effect transistor includes a substrate contact for electrically contacting the substrate, and the channel extends a first predetermined depth Y_{f} from the surface of the substrate and the Fermi-tub region extends a second predetermined depth Y₀ from the channel, and the Ferni-tub region is doped at a doping density which is a factor α times Nₛ, and the gate electrode includes a polysilicon layer of the first conductivity type and which is doped at a doping density Nₚ, the first predetermined depth (Y_{f}) is equal to:

$${Y}_{f} = \sqrt{\frac{2 {ϵ}_{s}}{{qN}_{s} α} \frac{kT}{q} Ln ( \frac{{N}_{p}}{{N}_{s}} )} , \qquad ( 2 )$$

where q is 1.6×10⁻¹⁹ coulombs and K is 1.38×10⁻²³ Joules/° Kelvin. The second predetermined depth (Y₀) is equal to:

$${Y}_{o} = \sqrt{\frac{2 {ϵ}_{s} {φ}_{s}}{{qN}_{s} α ( α + 1 )}} \qquad ( 3 )$$

where φₛ is equal to 2φ_{f}+kT/q Ln(α), and φ_{f} is the Fermi potential of the semiconductor substrate.

High Current Fermi-FET Structure

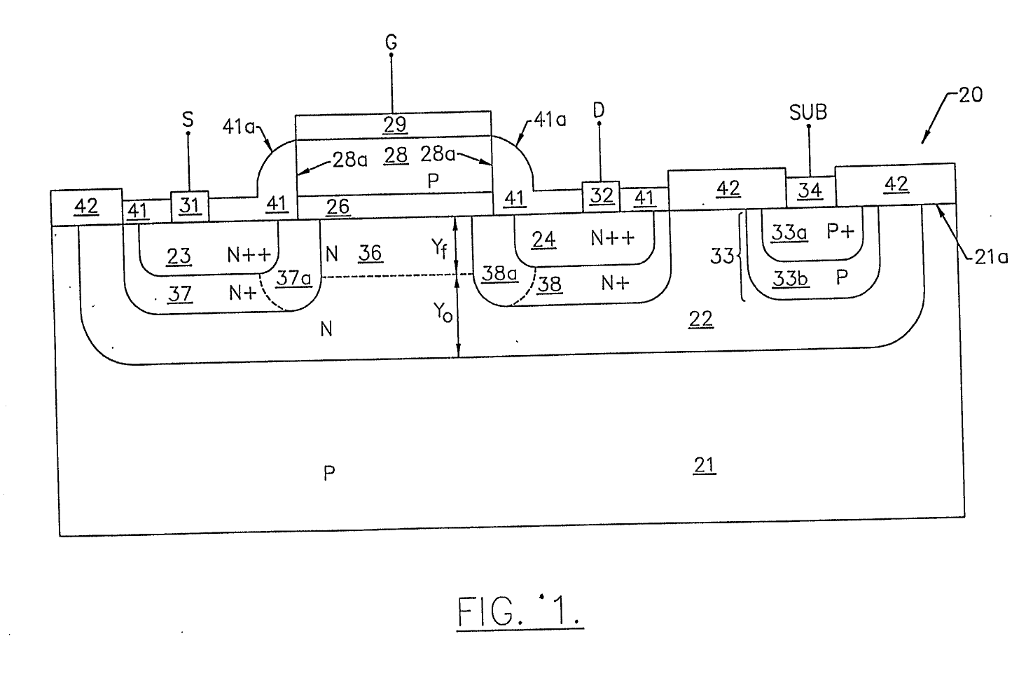

Referring now to FIG. 1, an N-channel high current Fermi-FET according to U.S. Pat. No. 5,374,836 is illustrated. It will be understood by those having skill in the art that a P-channel Fermi-FET may be obtained by reversing the conductivities of the N and P regions.

As illustrated in FIG. 1, high current Fermi-FET 20 is fabricated in a semiconductor substrate 21 having first conductivity type, here P-type, and including a substrate surface 21a. A Fermi-tub region 22 of second conductivity type, here N-type, is formed in the substrate 21 at the surface 21a. Spaced apart source and drain regions 23 and 24, respectively, of the second conductivity type, here N-type, are formed in the Fermi-tub region 22 at the surface 21a. It will be understood by those having skill in the art that the source and drain regions may also be formed in a trench in the surface 21a.

A gate insulating layer 26 is formed on the substrate 21 at the surface 21a between the spaced apart source and drain regions 23 and 24, respectively. As is well known to those having skill in the art, the gate insulating layer is typically silicon dioxide. However, silicon nitride and other insulators may be used.

A gate electrode is formed on gate insulating layer 26, opposite the substrate 21. The gate electrode preferably includes a polycrystalline silicon (polysilicon) gate electrode layer 28 of first conductivity type, here P-type. A conductor gate electrode layer, typically a metal gate electrode layer 29, is formed on polysilicon gate electrode 28 opposite gate insulating layer 26. Source electrode 31 and drain electrode 32, typically metal, are also formed on source region 23 and drain region 24, respectively.

A substrate contact 33 of first conductivity type, here P-type, is also formed in substrate 21, either inside Fermi-tub 22 as shown or outside tub 22. As shown, substrate contact 33 is doped first conductivity type, here P-type, and may include a relatively heavily doped region 33a and a relatively lightly doped region 33b. A substrate electrode 34 establishes electrical contact to the substrate.

The structure heretofore described with respect to FIG. 1 corresponds to the low capacitance Fermi-FET structure of U.S. Pat. Nos. 5,194,923 and 5,369,295. As already described in these applications, a channel 36 is created between the source and drain regions 23 and 24. The depth of the channel from the surface 21a, designated at Y_{f} in FIG. 1, and the depth from the bottom of the channel to the bottom of the Fermi-tub 22, designated as Y₀ in FIG. 1, along with the doping levels of the substrate 21, tub region 22, and polysilicon gate electrode 28 are selected to provide a high performance, low capacitance field effect transistor using the relationships of Equations (2) and (3) above.

Still referring to FIG. 1, a source injector region 37a of second conductivity type, here N-type, is provided adjacent the source region 23 and facing the drain region. The source injector region provides a high current, Fermi-FET by controlling the depth at which carriers are injected into channel 36. The source injector region 37a may only extend between the source region 23 and the drain region 24. The source injector region preferably surrounds source region 23 to form a source injector tub region 37, as illustrated in FIG. 1. Source region 23 may be fully surrounded by the source injector tub region 37, on the side and bottom surface. Alternatively, source region 23 may be surrounded by the source injector tub region 37 on the side, but may protrude through the source injector tub region 37 at the bottom. Still alternatively, source injector region 37a may extend into substrate 21, to the junction between Fermi-tub 22 and substrate 21. A drain injector region 38a, preferably a drain injector tub region 38 surrounding drain region 24, is also preferably provided.

Source injector region 37a and drain injector region 38a or source injector tub region 37 and drain injector tub region 38, are preferably doped the second conductivity type, here N-type, at a doping level which is intermediate the relatively low doping level of Fermi-tub 22 and the relatively high doping level of source 23 and drain 24. Accordingly, as illustrated in FIG. 1, Fermi-tub 22 is designated as being N, source and drain injector tub regions 37, 38 are designated as N⁺ and source and drain regions 23, 24 are designated as N⁺⁺. A unijunction transistor is thereby formed.

The high current Ferni-FET provides drive currents that are about four times that of state of the art FETs. Gate capacitance is about half that of a conventional FET device. The doping concentration of the source injector tub region 37 controls the depth of carriers injected into the channel region 36, typically to about 1000 Å. The source injector tub region 37 doping concentration is typically 2E18, and preferably has a depth at least as great as the desired maximum depth of injected majority carriers. Alternatively, it may extend as deep as the Fermi-tub region 22 to minimize subthreshold leakage current, as will be described below. It will be shown that the carrier concentration injected into the channel 36 cannot exceed the doping concentration of the source injector region 37a facing the drain. The width of the portion of source injector region 37a facing the drain is typically in the range of 0.05-0.15 μm. The doping concentration of the source and drain regions 23 and 24 respectively, is typically 1E19 or greater. The depth Y_{T}=(Y_{f}|Y₀) of the Fermi-tub 22 is approximately 2200 Å with a doping concentration of approximately 1.8E16.

As illustrated in FIG. 1, the high current Fermi-FET 20 also includes a gate sidewall spacer 41 on the substrate surface 21a, which extends from adjacent the source injector region 37a to adjacent the polysilicon gate electrode 28. Gate sidewall spacer 41 also preferably extends from adjacent the drain injector region 38a to adjacent the polysilicon gate electrode 28. In particular, as shown in FIG. 1, gate sidewall spacer 41 extends from the polysilicon gate electrode sidewall 28a and overlies the source and drain injector regions 37a and 38a respectively. Preferably the gate sidewall spacer 41 surrounds the polysilicon gate electrode 28. Also preferably, and as will be discussed in detail below, the gate insulating layer 26 extends onto the source injector region 37a and the drain injector region 38a at the substrate face 21a and the gate sidewall spacer 41 also extends onto the source injector region 37 and drain injector region 38.

The gate sidewall spacer 41 lowers the pinch-off voltage of the Fermi-FET and increases its saturation current in a manner in which will be described in detail below. Preferably, the gate sidewall spacer is an insulator having a permittivity which is greater than the permittivity of the gate insulating layer 26. Thus, for example, if the gate insulating layer 26 is silicon dioxide, the gate sidewall spacer is preferably silicon nitride. If the gate insulating layer 26 is silicon nitride, the gate sidewall spacer is preferably an insulator which has permittivity greater than silicon nitride.

As shown in FIG. 1, the gate sidewall spacer 41 may also extend onto source and drain regions 23 and 24 respectively, and the source and drain electrodes 31 and 32 respectively may be formed in the extension of the gate sidewall spacer region. Conventional field oxide or other insulator 42 regions separate the source, drain and substrate contacts. It will also be understood by those having skill in the art that although the outer surface 41a of gate sidewall spacer 41 is illustrated as being curved in cross section, other shapes may be used, such as a linear outer surface to produce a triangular cross section or orthogonal outer surfaces to produce a rectangular cross section.

Low Leakage Current Fermi-Threshold Field Effect Transistor

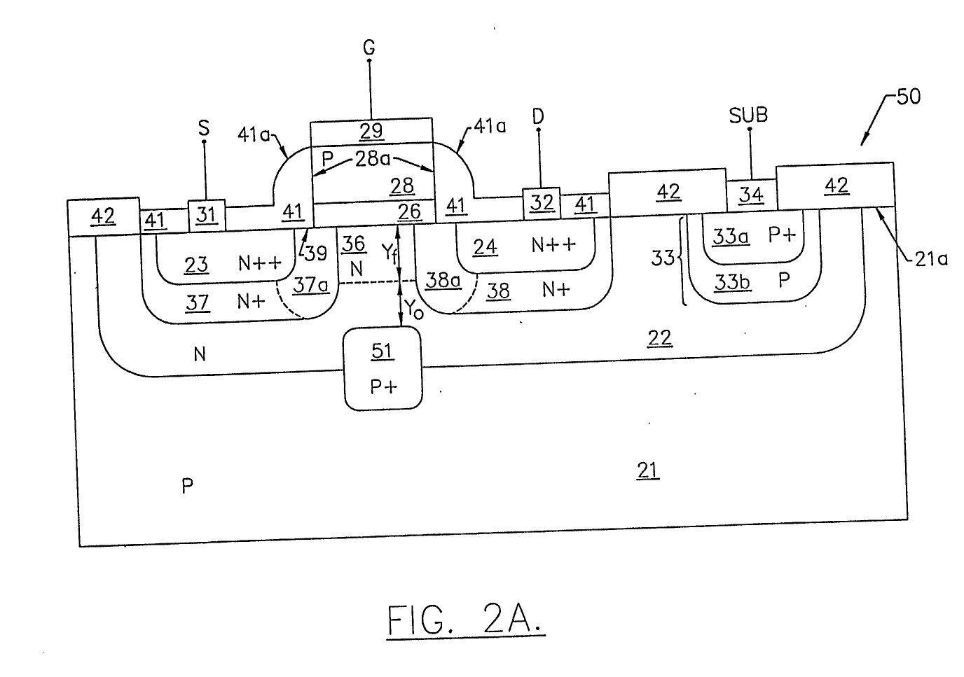

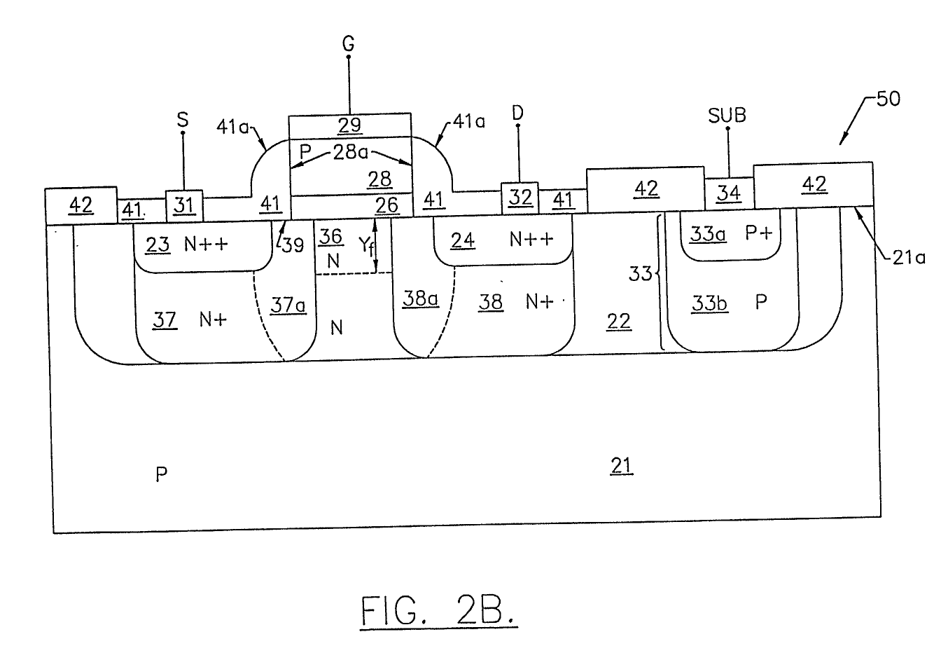

Referring now to FIGS. 2A and 2B, Fermi-FETs which have short channels yet produce low leakage current, according to U.S. Pat. No. 5,374,836 will now be described. These devices will hereinafter be referred to as “low leakage current Fermi-FETs”. The low leakage current Fermi-FET 50 of FIG. 2A includes a bottom leakage current control region 51 of first conductivity type, here P conductivity type, and doped at a high concentration relative to the substrate 21. Accordingly, it is designated as P+in FIG. 2A. The low leakage current Fermi-FET 60 of FIG. 2B includes extended source and drain injector regions 37a, 38a, which preferably extend to the depth of the Fermi-tub 22.

Referring now to FIG. 2A, bottom leakage current control region 51 extends across the substrate 21 from between an extension of the facing ends of the source and drain regions 23 and 24, and extends into the substrate from above the depth of the Fermi-tub 22 to below the depth of the Fermi-tub. Preferably, it is located below, and in alignment with the Fermi-channel 36. For consistency with the equations previously described, the depth from the Fermi-channel 36 to the top of the bottom current leakage current control region 51 has been labeled Y₀. The remainder of the Fermi-FET transistor of FIG. 2A is identical with that described in FIG. 1, except that a shorter channel is illustrated. It will be understood by those having skill in the art that injector regions 37a and 38a and/or injector tubs 37 and 38 may be omitted, as may the gate sidewall spacer region 41, to provide a low leakage current low capacitance, short channel Fermi-FET without the high current properties of the device of FIG. 2A.

The bottom leakage current control region 51 minimizes drain induced injection in short channel Fermi field effect transistors, i.e. those field effect transistors having a channel length of approximately 0.5 μm or less, while maintaining low diffusion depletion capacitance. For example, at 5 volts, leakage current of 3E-13A or less may be maintained.

The bottom leakage current control region may be designed using Equations (2) and (3) where Y₀ is the depth from the channel to the top of the bottom leakage control region as shown in FIGS. 2A and 2B. Factor α is the ratio between the P⁺ doping of the bottom leakage current control region 51 and the N doping of the Fermi-tub 22. Preferably α is set to about 0.15 within the bottom leakage control region, i.e. below the gate 28. Below the source and drain regions 23 and 24, α is set to about 1.0 to minimize diffusion depletion capacitance. In other words, the doping concentrations of substrate 21 and Fermi-tub 22 are about equal in the regions below the source and drain. Accordingly, for the design parameters described above, and for a channel width of 0.5 micron, the doping concentration in the bottom leakage control region 51 is approximately 5E17 and is deep enough to support partial depletion at the tub-junction region given 5 volt drain or source diffusion potential.

Referring now to FIG. 2B, an alternate design for bottom leakage control extends the depth of source injector region 37a and drain injector region 38a, preferably to the depth of the Fermi-tub (Y_{f}+Y₀). As shown in FIG. 2B, the depth of the entire source injector tub 37 and drain injector tub 38 may be extended, preferably to the depth of the Fermi-tub. The separation distance between the bottom of the injector tubs 37 and 38 and the bottom of the Fermi-tub 22 is preferably less than half the channel length and preferably approaches zero. Under these conditions, injector tubs 37 and 38 have doping concentration of about 1.5E18/cm³. The depth of substrate contact region 33b also preferably is extended to approach the Fermi-tub depth. The remainder of the Fermi-FET transistor 60 of FIG. 2B is identical with that described in FIG. 1, except that a shorter channel is illustrated.

Contoured-Tub Fermi-Threshold Field Effect Transistor

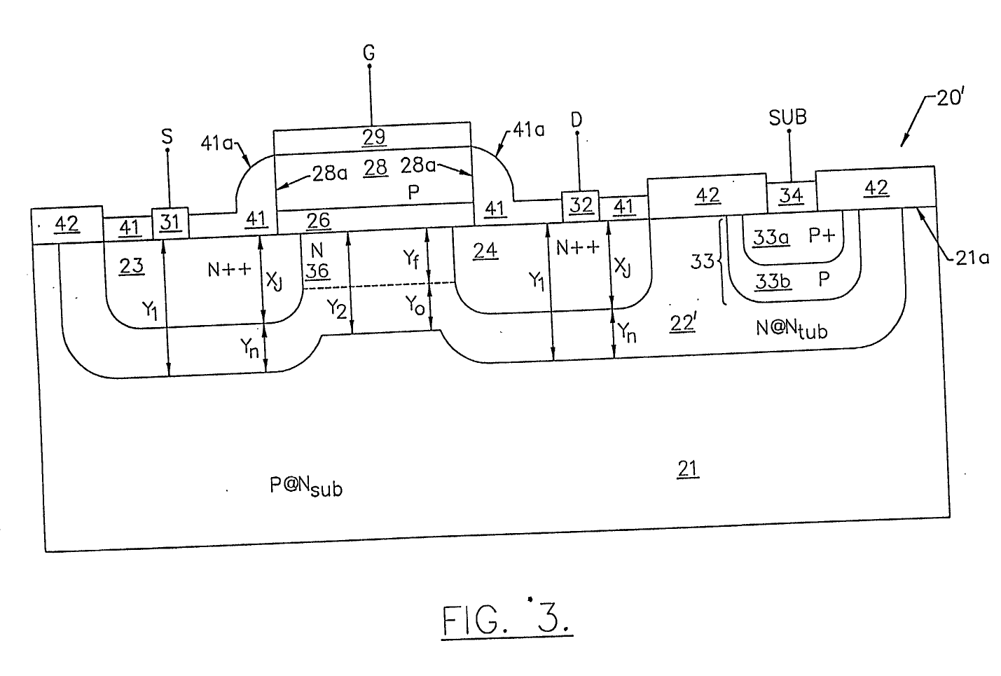

Referring now to FIG. 3, an N-channel contoured-tub Fermi-FET according to U.S. Pat. No. 5,543,654 is illustrated. It will be understood by those having skill in the art that a P-channel Fermi-FET may be obtained by reversing the conductivities of the N and P regions. As illustrated in FIG. 3, contoured-tub Fermi-FET 20′ is similar to high current Fermi-FET 20 of FIG. 1, except that a contoured-tub 22′ is present rather than the tub 22 of FIG. 1 which has a uniform tub depth. Injector tubs and injector regions are not shown, although they may be present.

Still referring to FIG. 3, contoured-tub 22′ has a first predetermined depth Y₁ from the substrate face 21a to below at least one of the spaced-apart source and drain regions 23, 24 respectively. The contoured-tub 22′ has a second predetermined depth Y₂ from the substrate face 21a to below the channel region 36. According to the invention, Y2 is different from, and preferably less than, Y₁ so as to create a contoured-tub 22′. Stated another way, the junction between tub 22′ and substrate 21 is pushed downward, away from source and drain regions 23 and 24, relative to the position dictated by the tub-FET criteria under the channel, to reduce the source/drain diffusion capacitance and thereby allow the contoured-tub Fermi-FET to operate at low voltages. It will be understood by those having skill in the art that tub 22′ may only be contoured under source region 23 or drain region 24 to produce an asymmetric device. However, symmetric devices in which the tub is contoured under source 23 and drain 24 are preferably formed.

The second predetermined depth Y₂ is selected based on the low capacitance Fermi-FET (Tub-FET) criteria of U.S. Pat. Nos. 5,194,923 and 5,369,295. These criteria, which determine the depths Y_{f} and Y₀, and which together form the second predetermined depth Y₂, are described above.

The first predetermined depth (Y₁) is selected to be greater than the second predetermined depth Y₂. Preferably, the first predetermined depth is also selected to deplete the tub region 22′ between the first predetermined depth Y₁ and the source and/or drain regions when zero voltage is applied to the source contact 31 and drain contact 32 respectively. Thus, the entire region labeled Yₙ is preferably totally depleted under zero source bias or drain bias respectively. Based on this criteria, Y₁ is determined by:

$${Y}_{n} = \sqrt{\frac{kT}{q} Ln ( \frac{{N}_{sub} {N}_{tub}}{{n}_{i}^{2}} ) \frac{2 {ϵ}_{s}}{{qN}_{sub}} \frac{1}{( 1 + \frac{{N}_{sub}}{{N}_{tub}} )}} \qquad ( 4 )$$

where N_{sub} is the doping concentration of the substrate 21 and N_{tub} is the doping concentration of the contoured-tub 22′.

Short Channel Fermi-FETs

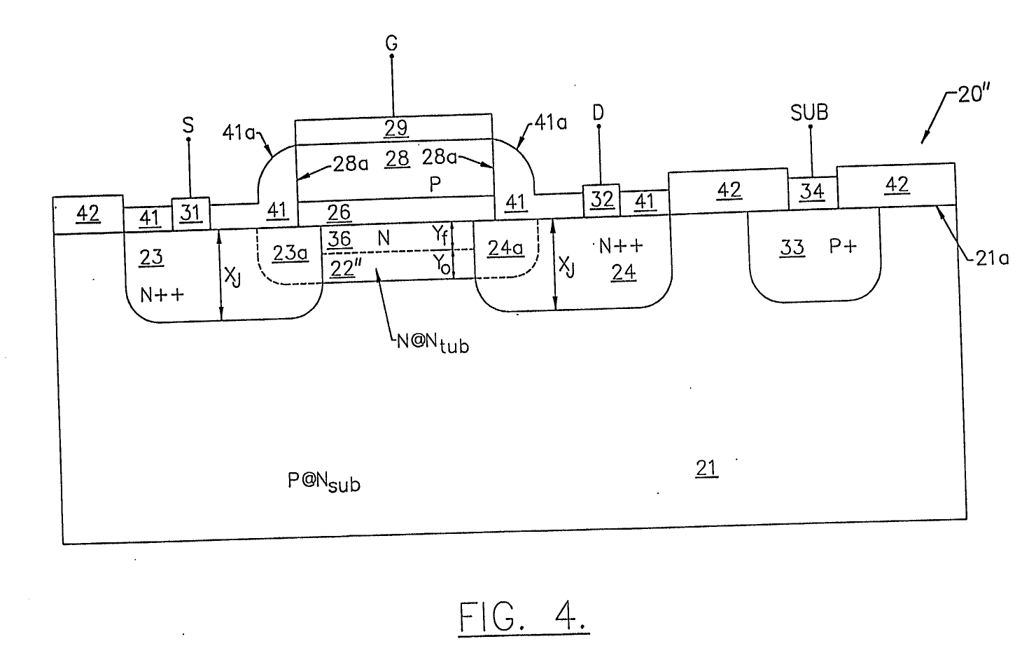

Referring now to FIG. 4, a short channel N-channel Fermi-FET 20″ according to application Ser. No. 08/505,085 is illustrated. It will be understood by those having skill in the art that a P-channel short channel Fermi-FET may be obtained by reversing the conductivities of the N and P regions. As shown in FIG. 4, Fermi-tub 22″ extends a first depth (Y_{f}+Y₀) from the substrate surface 21a. The spaced-apart source and drain regions 23 and 24 respectively are located in the tub region, as shown by regions 23a and 24a. However, the source and drain regions 23 and 24 respectively also extend from the substrate surface 21a to beyond the tub depth. Source and drain regions 23 and 24 also extend laterally in a direction along substrate surface 21a, to beyond the tub region.

The channel depth Y_{f} and the tub depth from the channel Y₀ are selected to minimize the static electric field perpendicular to the substrate surface in the channel 36 from the substrate surface to the depth Y_{f} when the gate electrode is at threshold potential. As already described, these depths are also preferably selected to produce a threshold voltage for the field effect transistor which is twice the Fermi potential of the semiconductor substrate 21. These depths are also selected to allow carriers of the second conductivity type to flow from the source region to the drain region in the channel region, extending from the depth Y_{f} toward the substrate surface 21a upon application of voltage to the gate electrode beyond the threshold voltage of the field effect transistor. Carriers flow within the channel region from the source region to the drain region underneath the substrate surface without creating an inversion layer in the channel. Accordingly, while not optimum, the device of FIG. 4 can still produce saturation currents far higher than traditional MOSFET transistors, with significant reductions in off-state gate capacitance. Drain capacitance becomes similar to standard MOSFET devices.

It will be understood that in FIG. 4, the source and drain regions extend beyond the tub region in the depth direction orthogonal to substrate face 21a, and also in the lateral direction parallel to substrate face 21a. However, in order to decrease the parasitic sidewall capacitance, the tub 22″ preferably extends laterally beyond the source and drain regions, so that the source and drain regions only project through the tub in the depth direction.

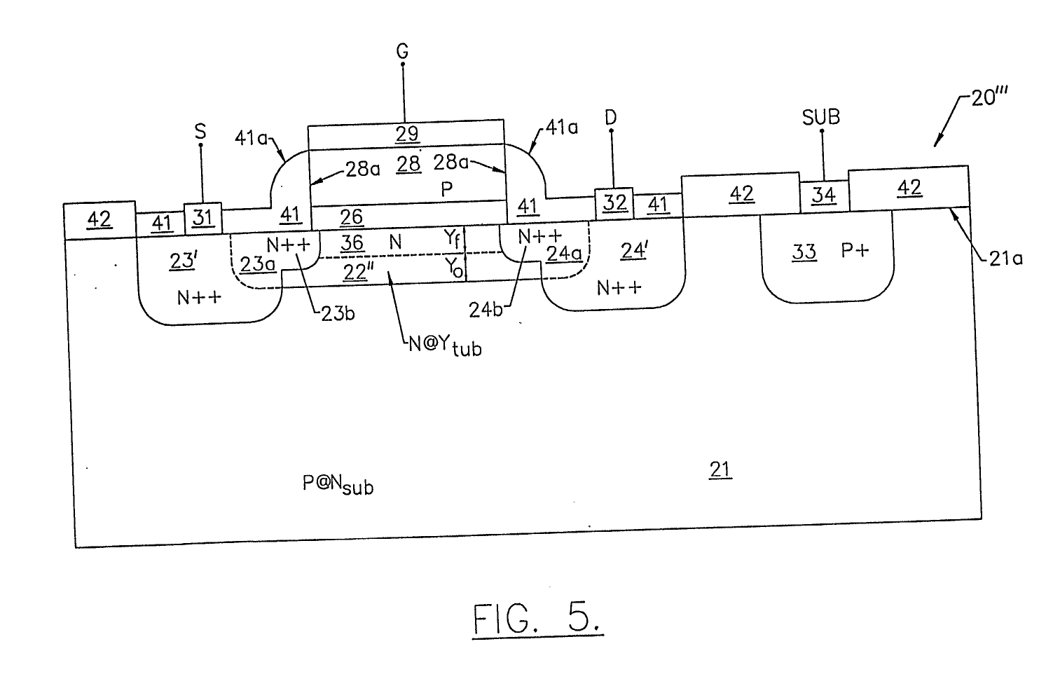

Referring now to FIG. 5, a second embodiment of a short channel Fermi-FET according to application Ser. No. 08/505,085 is illustrated. Transistor 20′″ is similar to transistor 20″ of FIG. 4 except that source and drain extension regions 23b and 24b respectively are provided in the substrate 21 at the substrate face 21a adjacent the source region and drain regions 23′ and 24′ respectively, extending into channel 36.

As shown in FIG. 5, source and drain extension regions 23b and 24b respectively are heavily doped (N⁺⁺), at approximately the same doping concentration as source and drain regions 23′ and 24′. It will be understood that the extensions 23b and 24b are not lightly doped as are lightly doped drain structures of conventional MOSFET devices. Rather, they are doped at the same doping concentration as the source and drain region, and are preferably as highly doped as practical in order to reduce leakage and improve saturation current.

The source and drain extension regions 23b and 24b reduce drain voltage sensitivity due to the charge sharing described above. Unfortunately, the device of FIG. 5 will generally not display as low a capacitance as the fully enclosed source and drain regions of FIGS. 1 and 2. It will be understood by those having skill in the art that in order to preserve the dimensions of the source/drain extension regions 23b and 24b, a heavy, slow moving dopant such as arsenic or indium is preferably used for the source and drain extension regions rather than a lighter, faster moving element which is typically used for the source and drain regions themselves.

Short Channel Fermi-FET Including Drain Field Termination

The architecture of short channel Fermi-threshold field effect transistors including drain field termination regions, also referred to herein as Vinal-FETs, according to U.S. Pat. No. No. 5,698,884, will now be described. It will be understood by those having skill in the art that P-channel Vinal-FETs may be obtained by reversing the conductivity of the N- and P-regions.

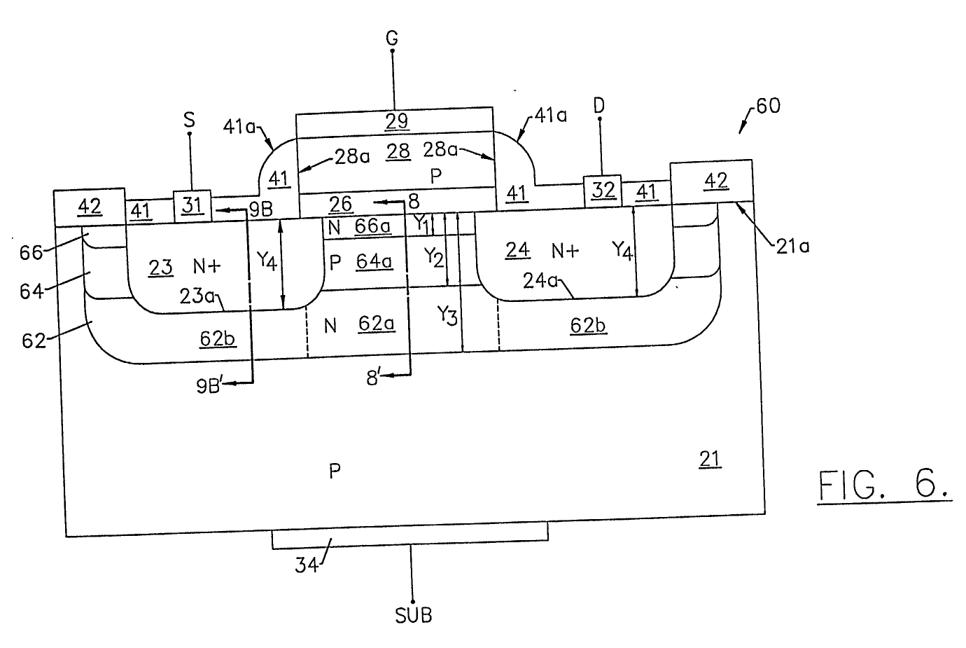

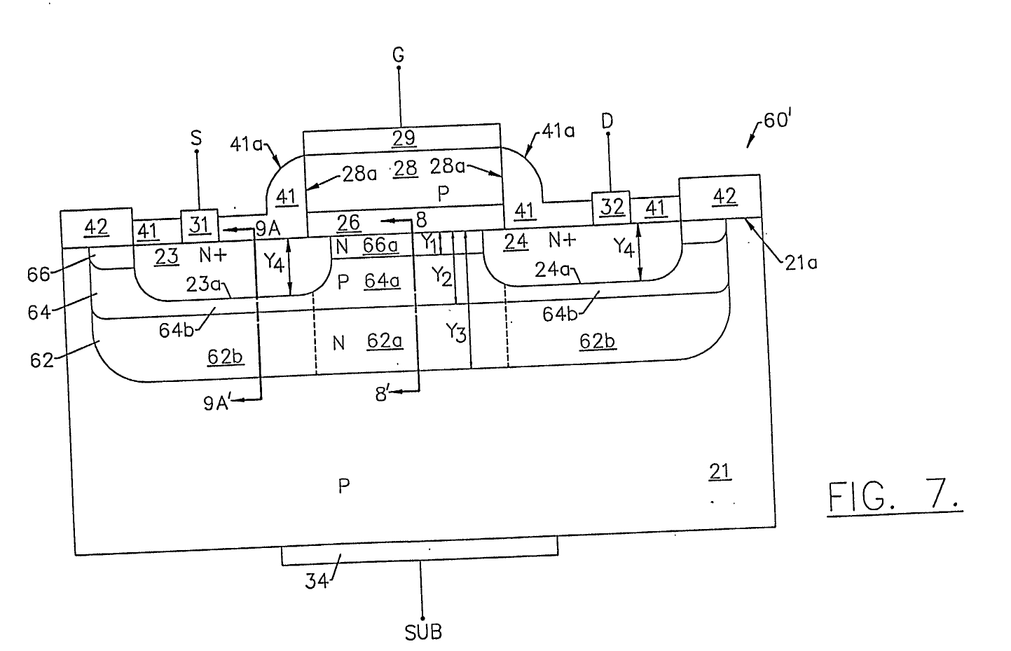

FIGS. 6 and 7 illustrate first and second embodiments of a Vinal-FET respectively. As shown in FIG. 6, Vinal-FET 60 includes a semiconductor substrate 21 of first conductivity type, here P-type. It will be understood by those having skill in the art that semiconductor substrate 21 may also include one or more epitaxial layers formed on a bulk semiconductor material so that the substrate surface 21a may actually be the outer surface of an epitaxial layer rather than the outer surface of bulk semiconductor material.

Still referring to FIG. 6, a first tub region 62 of second conductivity type (here N-type) is formed on the substrate 21 at surface 21a and extending into the substrate a first depth Y₃ from the substrate surface 21a. A second tub region 64 of the first conductivity type, here P-type, is included in the first tub region 62. Second tub region 64 extends into the substrate a second depth Y₂ from substrate surface 21a, with the second depth Y₂ being less than a first depth Y₃. The second tub region 64 in the first tub region 62 may also extend laterally beyond first tub region 62. Second tub region 64 forms a Drain Field Terminating (DFT) region as will be described below. A third tub region 66 of the second conductivity type, here N-type, is included in the second tub region 64. The third tub 66 extends into the substrate 21 a third depth Y₁ from the substrate surface wherein the third depth Y₁ is less than the second depth. Third tub 66 is preferably formed in an epitaxial layer as will be described below.

Still referring to FIG. 6, spaced apart source and drain regions 23 and 24 respectively, of the second conductivity type (here N+), are formed in the first tub region 62 and extend into the substrate a fourth depth Y₄ from the substrate surface 21a. As shown in FIG. 6, the fourth depth Y₄ is greater than the third depth Y₁. As shown in FIG. 6, fourth depth Y₄ is also greater than the second depth Y₂, but is less than the first depth Y₃. Accordingly, the source and drain diffusions 23 and 24 respectively, extend through the third and second tubs 66 and 64 respectively, and into the first tub 62. In a second embodiment of a Vinal-FET 60′ as shown in FIG. 7, the fourth depth Y₄ is greater than the third depth Y₁ but is less than the second depth Y₂, so that the source and drain regions extend through the third tub 66 and into the second tub 64, but do not extend into the first tub 62.

Vinal-FET transistors 60 and 60′ of FIGS. 6 and 7 respectively, also include a gate insulating layer 26 and a gate electrode including polycrystalline silicon layer 28 of the first conductivity type, here P-type. Source, gate and drain contacts 31, 29 and 32 are also included as already described. A substrate contact 34 is also included. The substrate contact is shown opposite surface 21a but it may also be formed adjacent surface 21a as in previous embodiments.

The Vinal-FETs 60 and 60′ of FIGS. 6 and 7 may also be described from the perspective of the layers in the substrate 21 which extend between the source and drain regions 24. When viewed in this regard, third tub 66 produces a first layer 66a of a second conductivity type in the substrate at the substrate surface which extends from the source region 23 to the drain region 24 and also extends into the substrate a first depth Y₁ from the substrate surface. Second tub 64 produces a second layer 64a of the first conductivity type in the substrate which extends from the source region 23 to the drain region 24 and extends into the substrate from the first depth Y₁ to a second depth Y₂ from the substrate surface. Second layer 64a acts as Drain Field Terminating means as described below. First tub 62 produces a third layer 62a of the second conductivity type in the substrate which extends from the source region to the drain region and extends into the substrate from the second depth Y₂ to a third depth Y₃ from the substrate surface.

When viewed in this manner, in the embodiment of FIG. 6, the third layer 62a also extends from the source bottom 23a to the drain bottom 24a as indicated by regions 62b. In the embodiment of FIG. 7, the second and third layers 64a and 62a respectively, both extend from the source bottom 23a to the drain bottom 24a as shown at regions 64b and 62b respectively.

The Vinal-FET of FIGS. 6 and 7 may also be regarded as a Tub-FET which includes a contra-doped buried tub 64 within the original tub. Still alternatively, the Vinal-FET may be viewed as a Tub-FET which includes a buried layer of first conductivity type 64a beneath the channel region 66a. As will be described in detail below, second tub 64 including second layer 64a acts as Drain Field Terminating (DFT) means to shield the source region by preventing the applied drain bias from causing carriers to be injected from the source region into or below the channel region. Accordingly, second tub 64 and second layer 64a may also be referred to as a Drain Field Termination (DFT) region.

Operation of the Vinal-FET transistors 60 and 60′ of FIGS. 6 and 7 are described in detail in U.S. Pat. No. No. 5,698,884, and will not be described again herein.

Metal Gate Fermi-FET Transistors

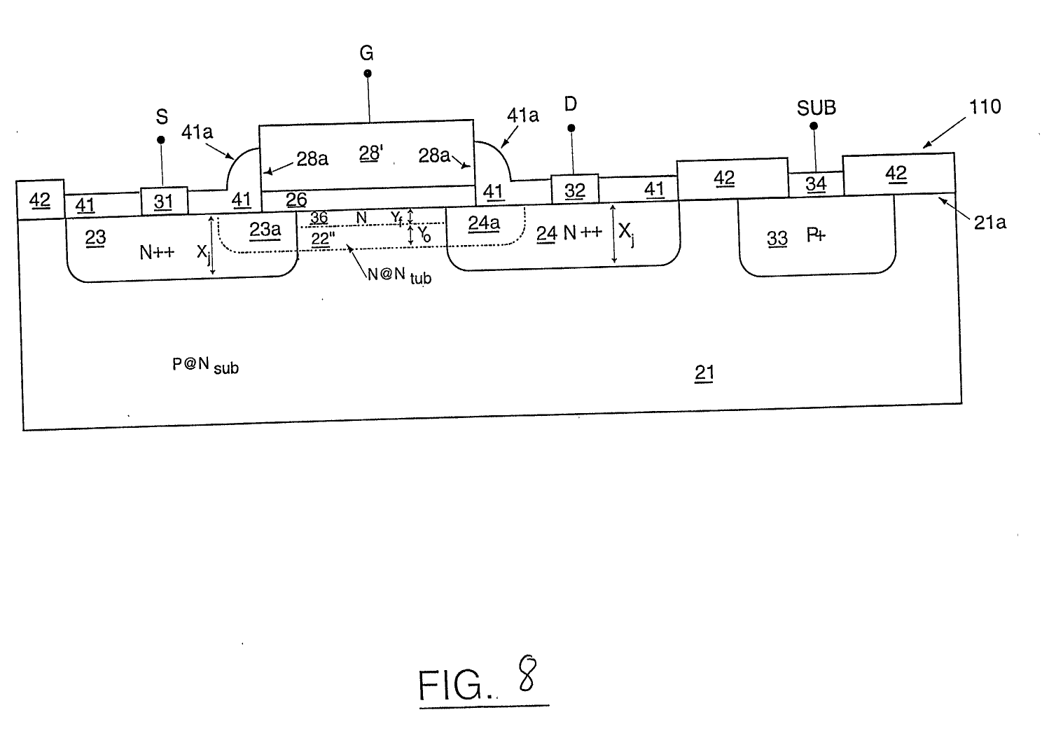

FIG. 8 illustrates an embodiment of a metal gate Fermi-FET, according to application Ser. No. 08/938,213. This embodiment is patterned after the N-channel, short-channel Fermi-FET of U.S. Pat. No. 5,543,654 that is illustrated in FIG. 4 of the present application. However, it will be recognized by those having skill in the art that metal gate Fermi-FET technology can be applied to all Fermi-FETs to lower the threshold voltage thereof.

As shown in FIG. 8, metal gate Fermi-FET 110 includes a metal gate 28′ rather than the P-type polysilicon gate 28 and metal gate electrode layer 29 of FIG. 4. For ease of illustration, all other elements of transistor 110 are unchanged from that of FIG. 4. Accordingly, as shown in FIG. 8, a metal gate 28′ is included directly on the gate insulating layer 26. Stated differently, the metal gate 28′ of the Fermi-FET 110 is free of doped polysilicon directly on the gate insulating layer 26. Thus, the contact potential is not controlled by the Fermi-potential of polysilicon. It will be understood that the metal gate may include multiple layers, wherein the layer that is directly on the gate insulating layer is free of doped polysilicon.

Operation of the metal gate Fermi-FET 110 of FIG. 8 is described in detail in application Ser. No. 08/938,213, and will not be described again herein.

Offset Drain Fermi-FET Transistors

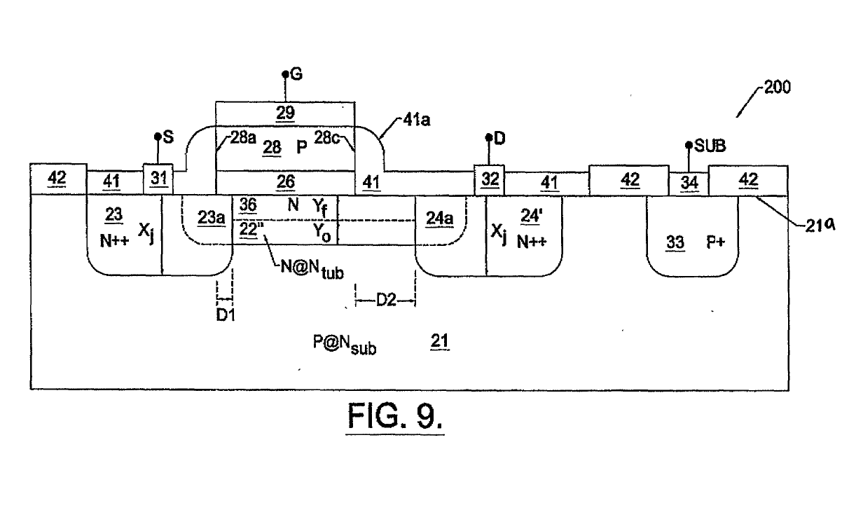

According to the invention, improved high voltage and/or high frequency transistors may be provided, by laterally offsetting the drain of a Fermi-FET. FIG. 9 illustrates a first embodiment of offset drain Fermi-FETs according to the present invention. This embodiment is patterned after the N-channel, short-channel Fermi-FET of U.S. Pat. No. 5,543,654 that is illustrated in FIG. 4 of the present application. However, it will be recognized by those having skill in the art that offset drain Fermi-FET technology can be applied to all Fermi-FETs to improve the high voltage and/or high frequency performance thereof.

As shown in FIG. 9, an offset drain Fermi-FET 200 includes a drain 24′ that is laterally offset from the gate electrode 28 compared to the source region 23. More specifically, as shown in FIG. 9, the gate electrode 28 includes first and second ends 28b and 28c respectively. The source region 23 is adjacent the first end 28b of the gate electrode 28, and the drain region 24′ is laterally spaced apart from the second end 28c of the gate electrode 28. As shown, the source region 23 is laterally spaced apart from the first end 286 of the gate electrode by a first distance D1 and the drain region 24′ is laterally spaced apart from the second end 28c of the gate electrode 28 by a second distance D2 that is greater than the first distance. It will be understood that the first distance D1 can be zero or, as illustrated in FIG. 9, can be negative. For ease of explanation, all other elements of transistor 200 are unchanged from that of FIG. 4.

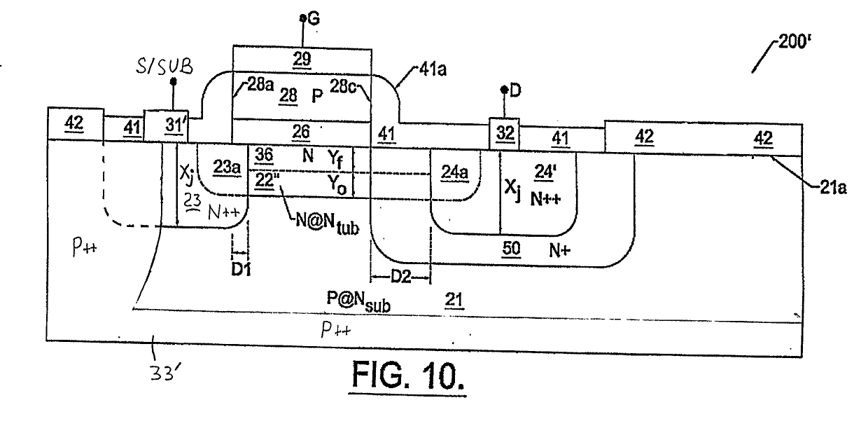

FIG. 10 illustrates a second embodiment of offset drain Fermi-FETs 200′ according to the present invention. As shown in FIG. 10, an offset drain Fermi-FET 200′ includes a drift region 50 between the drain region 24′ and the Fermi-FET channel 36. As also shown in FIG. 10, the drift region 50 may surround the drain region 24′. The drift region 50 is preferably doped the same conductivity type as the drain region, shown in FIG. 10 as N-type, at lower doping concentration. More preferably, as shown in FIG. 10, the drift region is preferably doped at an intermediate doping concentration between that of the channel 36 and the offset drain 24′.

As also shown in FIG. 10, an integrated source/substrate contact is provided rather than a separate substrate contact and substrate electrode of FIG. 9. In particular, an integrated source/substrate electrode 31′ contacts the source region 23 and an integrated substrate contact 33′. The integrated substrate contact 33′ extends to the bottom face of the substrate 21, and is heavily doped, here P⁺⁺. A three terminal device 200′, rather than a four terminal device 200 of FIG. 9 is provided. It will also be understood that the integrated source/substrate contact may also be used in the embodiment of FIG. 9.

A simulation of an offset drain Fermi-FET according to the invention, with a drawn linewidth of 0.30 μm will now be described. It will be understood that the results of this simulation are illustrative, and shall not be construed as limiting the present invention. Offset drain Fermi-FETs can provide high f_{T} output RF power devices which may be integrated with conventional CMOS technology. The Fermi-FET architecture, with high transconductance (gₘ) and low capacitances, is an attractive choice. A mixed CMOS/Fermi-FET technology may be implemented. Fermi-FET devices are defined by the behavior of the electric field in the channel, which in turn is defined by the channel engineering.

The Silvaco tools Athena version 4.3.1.R and Atlas version 4.3.0.R were used for process and electrical device simulation, respectively. For these simulations, the process flow is maintained simple, with little emphasis on the back-end process. Ideal contacts to the silicon and the polysilicon gate are assumed with no silicidation. Simple depositions are used when little impact is expected on the overall thermal budget. The device structure is planar with no LOCOS or other isolation formation, although the LOCOS thermal steps are included without the photolithography. The device structure follows a conventional CMOS flow. As shown, the Fermi-FET architecture can fit well within an existing CMOS technology line.

The process flow used is as follows:

Starting material: P-type 1.2×10¹⁵ cm⁻³

Initial oxide: 150 Å-850° C. steam, 9.7 min.

Nitride deposition: 1400 Å-765° C.

Field oxide deposition: 3500 Å-1050° C. steam, N₂/1%O₂

Sacrificial oxide: 230 Å-850° C. steam, 15.8 min.

P-well implant: 8.0×10¹² cm⁻³ boron at 100 KeV and 7° tilt

N-type channel implant: Fermi tub implant: 6.0×10¹¹ cm⁻³ phosphorus at 40 KeV and 7° tilt

Gate oxidation: 110 Å-800° C. steam, 14.3 min.

Poly gate deposition: 1200 Å

Poly gate implant: 1.6×10¹⁵ cm⁻³ boron at 15 KeV and 7° tilt

Poly gate oxide cap: 2200 ÅCVD oxide

Gate patterning

Gate re-ox oxidation (anneal): 850° C., 20 min. dry—approximately 50 Å sidewall oxide on poly

Drain offset photo: 0.3μm offset length nominally

N-LD implant (drain drift region): 7.0×10¹² cm⁻³ phosphorus at 40 KeV and 0° tilt

Source/drain photo

Source/drain N+ implant: 2.0×10¹⁵ cm⁻³ arsenic at 30 KeV and 7° tilt

Final RTA anneal: 1050° C., 20 secs.

Poly cap removal

Contact formation

The simulated device may experience the same degradations in performance due to thick gate oxide and the drain offset implant as conventional surface-channel LDMOS devices. However it is found that the relative degradation is less when compared with a surface-channel MOS device, due to the channel engineering of the Fermi-FET device. The channel is engineered to provide a minimal surface field, as close to zero as possible at V_{TH}. The field reduction impacts both the linear (triode) and saturation (pentode) characteristics due to reduced transverse field degradation of the mobility. For this device, the presence of the laterally diffused drift region and the thicker gate oxide allows the channel design to more closely match long-channel or ideal Fermi-FET design criteria.

In a short-channel Fermi-FET device, drain engineering may be used to reduce short-channel effects (SCE). For the present structure, this is less of a concern due to the lighter doped drain drift region, which drops a significant portion of the drain potential. Thus, there may be no need for conventional LDD, extension or pocket implants.

As described above, no silicidation models are used. The predicted source/drain junction depths may be somewhat shallow for siliciding reliably, but the junctions may be deepened. This may impact the L_{eff} to some degree, hence the short-channel effects, so deeper junctions may need to be approached with caution.

Concerning the gate and source/drain implants, in order to prevent the source/drain implants from compensating the boron poly implant, an oxide blocking film of 2200 Å is deposited on the gate. This film may by nitride or oxy-nitride as well. In the past, all three materials have been used, with the best results obtained from a pure nitride film. The gate patterning and etching with this film in place may need to be performed with care.

Note also that the gate implant is boron, rather than BF₂. This is used for much thinner oxides in order to reduce boron penetration through the gate oxide, since fluorine has been reported to enhance boron penetration. For the gate oxide thickness used here, boron penetration should not be a problem. Thus either boron or BF₂ may be used.

As with conventional Fermi-FET designs, the present device can provide a flat surface potential at the surface of the device at V_{TH}. This provides the zero field condition desired at V_{TH}, as well as the full depletion of the channel region by the channel-to-well junction. Another advantage to this device design approach is the reduction of the source/drain junction capacitance, due to the expanded depletion in the channel region, compared to a surface-channel device.

A poly gate blocking film may be used to prevent gate compensation from the source/drain implants, since the Fermi-FET gate preferably is contra-doped. An oxide blocking film is used in this flow, however nitride may be a better choice, based on previous experience.

For the simulation, the most physical models available in Athena are used. The fully coupled solution method was used with the cluster.dam, i.loop.sink and high.conc methods enabled to account for <311> clusters, interstitial sinks due to dislocation loop bands and enhanced point defect recombination. The unit.dam model is used for each implant to account for interstitial generation due to implant damage.

For all implants, Silvaco SVDP (SIMS Verified Dual Pearson) models are used. The moments for the dual Pearson model are table-based and computed over ranges from 1 to 200 KeV, depending upon species. All of the implants fell within Silvaco's data-verified SVDP model. The default implant damage coefficients are used for each species. The fully coupled diffusion method is used, as noted above. Transient-enhanced diffusion is automatically accounted for with the implant damage models enabled.

Table 1 summarizes the implant conditions. The thermal budget consists of the gate oxidation, gate re-ox and the final RTA anneal.

TABLE 1

| Implant | Species | Dose | Energy | Tilt | Rotation |
|---|---|---|---|---|---|
| P-well | boron | 8.0 × 10¹² cm⁻³ | 100 KeV | 7° | none |
| N-ft | phosphorus | 6.0 × 10¹¹ cm⁻³ | 40 KeV | 7° | none |
| P-poly | boron | 1.6 × 10¹⁵ cm⁻³ | 15 KeV | 7° | none |
| N-1d | phosphorus | 7.0 × 10¹² cm⁻³ | 10 KeV | 0° | none |
| N-sd | arsenic | 2.0 × 10¹⁵ cm⁻³ | 30 KeV | 7° | none |

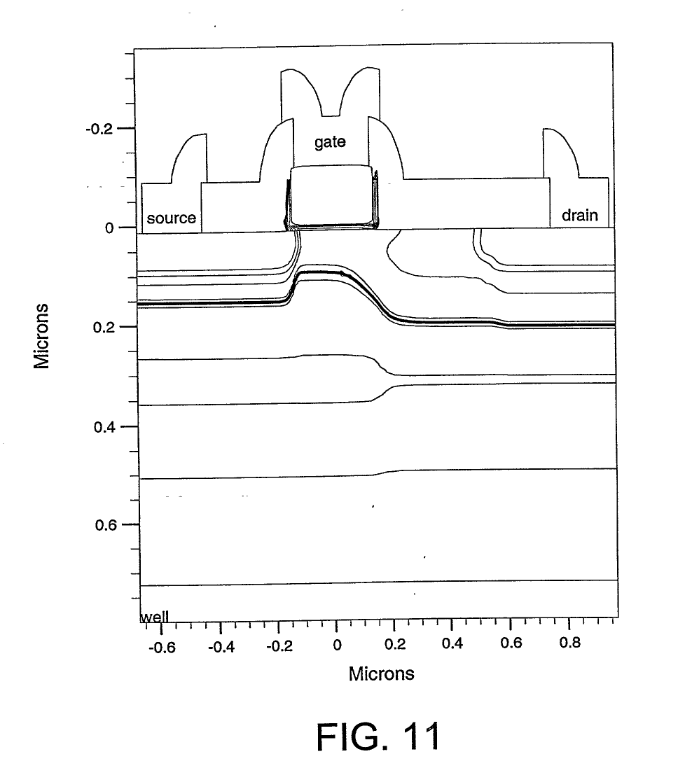

FIG. 11 illustrates a 2-D cross-section of the simulated N-channel device with L=0.30 μm and a drain offset that is equal to the gate length of 0.30 μm. From FIG. 11, the doping gradients are seen, along with the relative junction depths of the source/drain, channel and drift region implants. The N-to-P-well junction is delineated by the thick line.

As shown, dopings are typically lighter and deeper in a Fermi-FET channel compared to a conventional MOSFET channel, leading to good sub-threshold behavior, reduced fields and higher mobility. A properly designed Fermi-FET can exhibit a surface field very close to zero V/cm at threshold. Thus, the threshold voltage can equal the “flat-band” voltage.

In practice, due to non-uniform doping profiles, surface charge, material irregularities, and/or short-channel effects, a true flat-band voltage may not exist. Thus, some amount of surface-induced depletion may be necessary, and the transverse field may not be exactly zero. However, Fermi-FET devices may be designed to meet the ideal conditions as closely as possible, as is the case in the present simulation as well.

Table 2 summarizes some of the key device parameters.

TABLE 2

| Parameter | Value |
|---|---|
| N-tub Xⱼ | 866Å |
| P-well Xⱼ | 0.75 μm |
| N-LD Xⱼ | 1880Å |
| N+-S/D Xⱼ | 1400Å |
| Tₒₓ | 110Å |
| L_{eff} | 0.121 μm |

For Fermi-FETs, the L_{eff} is defined by measuring the distance between the source and drain roll-offs at the geometric mean of the mid-channel and source/drain peak dopings. For coarser technology designs, this value correlates well with the so-called “shift-and-ratio” L_{eff} extraction technique described in Taur et al., “A New ‘Shift and Ratio’ Method for MOSFET Channel-Length Extraction”, IEEE Electron Device Letters, Vol. 13, No. 5, May 1992, pp. 267-269, both for measured and simulated device characteristics. For this device, the drain-end lateral roll-off is shallower than the source, due to the additional drift region implant. Thus, the Leff is computed to be somewhat shorter than a conventional drain Fermi-FET.

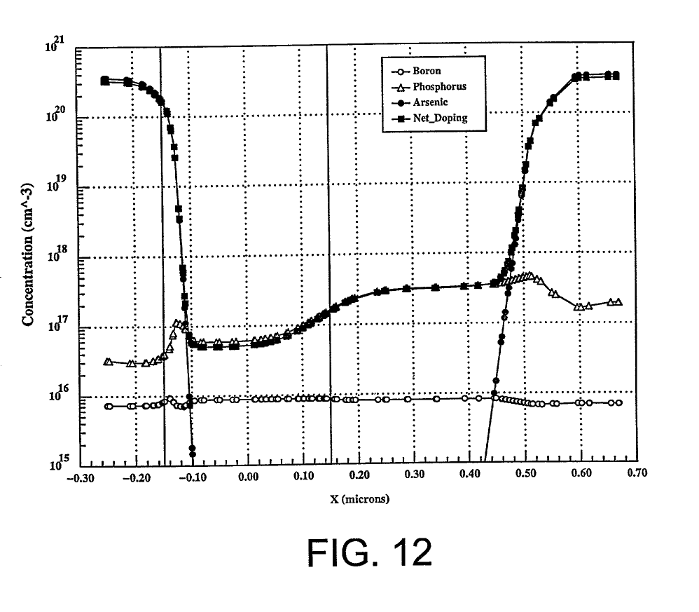

FIG. 12 shows the lateral doping profiles just under the silicon surface. The gate edges are delineated by the solid vertical lines at X=−0.15 μm and X=+0.15 μm. As described above, the asymmetry in the lateral profiles from the source-to-channel and drain-to-channel is clear.

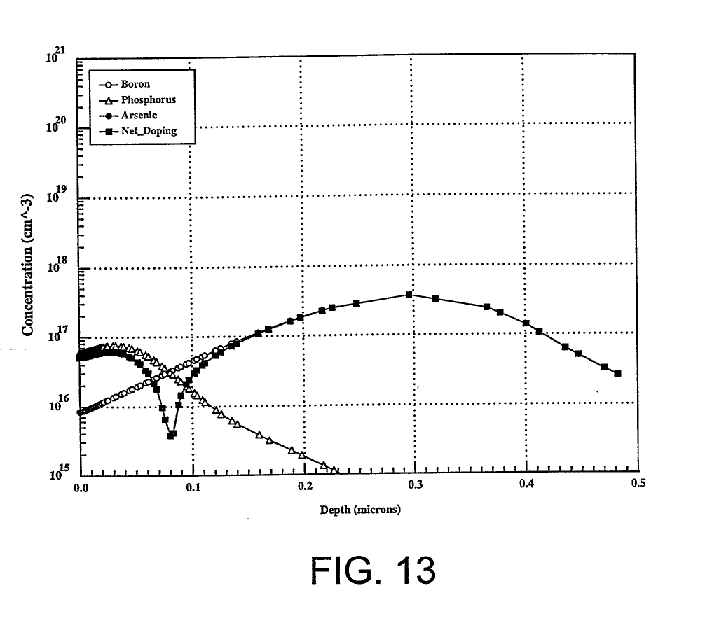

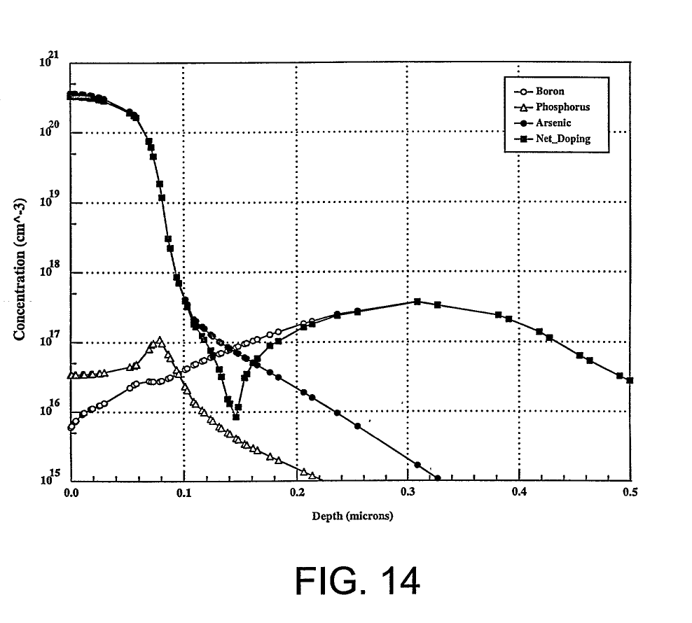

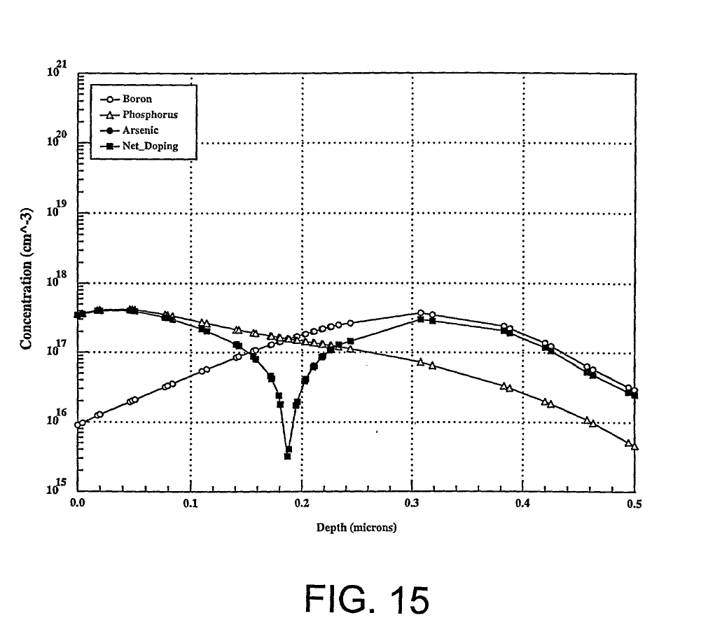

FIGS. 13, 14 and 15 show vertical doping profiles in the channel region, at the source/drain region and in the drain offset region, respectively. In FIG. 13, the channel tub depth can be seen to be about 850 Å, which may be desirable for good performance. In FIG. 14, the source is seen to be on the order of 1400 Å. This should be acceptable for siliciding, but may be deepened somewhat if desired. In FIG. 15, the drain implant depth is about 1800 Å. This should provide a breakdown threshold of about 12V.

Compared to a conventional MOSFET or Fermi-FET to be used for digital applications, additional factors may be considered in high voltage and/or high frequency devices. It is desired to maximize performance in terms of speed. Increasing drive current and reducing capacitance can achieve this as far as the large-signal dynamic performance of a circuit is concerned. For an RF power device, however, additional characteristics may need to be considered.

For linear power applications, an RF driver may be biased in a Class A common-source amplifier configuration. In this case, an idle or bias current always flows through the device. Thus, the device dissipates DC power. Source-to-drain leakage current may not be an issue, as long as the DC bias point is not disturbed due to excessive leakage, particularly at high operating temperatures. A common figure is the power-add efficiency (PAE) which describes the available output power ratioed to the total DC and input power applied to the device. For the present simulation, an estimate of PAE was not attempted.

For good power performance, a device with a gₘ below unity, and a low on-resistance R_{DS} may be desired. Thus, the device widths (W_{eff}) are often on the order of millimeters, or tens of millimeters wide. Careful attention may need to be paid to thermal characteristics during layout to allow optimal performance at operating temperatures. It appears that Fermi-FET thermal characteristics may be tuned, allowing a much smaller RDS thermal coefficient. This leads to the promise of smaller total device area, hence reduced thermal gradient effects.

For channel lengths below about L=0.25 μm, velocity overshoot or ballistic carrier transport may also be considered. For N-channel devices at L=0.30 μm, this may be less of a concern, but simulations indicate 10% to 15% higher drive currents with these effects included. Additionally, there may be a significant impact on substrate current by including these models. Atlas handles this through an energy balance model, which adds an extra set of continuity equations for the carrier temperatures. Though computationally expensive, the energy-balance model may provide more physical looking I-V characteristics. The default relaxation times are used for the present simulation.

The low-field mobility model used is Silvaco's CVT model with default parameters. This model has yielded the closest correlation with actual silicon. SRH recombination, concentration-dependent mobility and full Newton 2-carrier solutions are used as well.

In addition to the operating characteristics, an RF power device also should have a robust breakdown voltage since the device interfaces directly with external reactive components with relatively large component values. Large inductive voltage spikes can appear at the drain of the device. In order to simulate avalanche breakdown with a slowly varying transient voltage on the drain, the Selberherr impact ionization model is used in Atlas. The default coefficients are used, since no silicon data is available to tune the ionization coefficients. The impact ionization model may not be used with the energy-balance model, so the breakdown is studied only at V_{G}=0.0 volts.

For these simulations, a supply voltage (V_{DD}) of 3.3 volts is used. The parameters measured are based on log(I_{DSAT}) vs. V_{GS} curves at V_{DS}=0.1 V and V_{DS}=3.3 V. Table 3 shows some key parameters extracted from these curves.

TABLE 3

| Param | Conditions | Value | Units |
|---|---|---|---|
| V_{TH1} | V_{GS} where I_{DS} = 0.5 μA | 0.864 | Volts |
| | with V_{DS} = 0.1 V | | |
| V_{TH2} | V_{GS} where I_{DS} = 0.5 μA | 0.688 | Volts |
| | with V_{DS} = 3.3 V | | |
| V_{THL} | Max. gₘ extrapolated | 0.910 | Volts |
| | V_{TH} with V_{DS} = 0.1 V | | |
| I_{DSAT} | I_{DS} with V_{DS} = V_{GS} = 3.3 | 508.6 | μA/μm |
| | V | | |
| I_{DOFF} | I_{DS} with V_{DS} = 3.3 V, | 3.02 | pA/μm |
| | V_{GS} = 0.0 V | | |
| D_{IBL} | (V_{TH2}—V_{TH1})/3.3 | 53.3 | mV/V |
| S | δV_{GS}/δI_{DS} at I_{DS} = 10⁻⁸ | 108 | mV/dec. |
| | with V_{DS = 0.1 V} | | |
| S | δV_{GS}/δI_{DS} at I_{DS} = 10⁻⁸ | 127 | mV/dec. |
| | with V_{DS} = 3.3 V | | |

The V_{TH} value used is the current value threshold, V_{TH1}. For previous technologies, it has provided a value fairly close to theoretical calculations of V_{TH}. This definition can allow easy determination of DIBL and is often used to characterize SOI FETs. The V_{TH1} values, while somewhat high for this line-width, still provide V_{DD} to V_{TH} ratios of 3.8 to 4.8, which is quite desirable from a design perspective. Note that the Fermi-FET can deliver higher drive current at a higher threshold voltage. This can have positive design implications from the standpoint of noise immunity.

The simulated DIBL value of 53 mV/V may also be somewhat high. A more desirable value would be 30 or 35 mV/V. DIBL may be undesirable from a manufacturing perspective since it may indicate high SCE, thus poor V_{TH} control, particularly with gate patterning variations. For digital applications this can lead to excessive off-state leakage, poor noise immunity and even nonfunctional circuitry. For linear applications, however, the main effect of DIBL is to increase the output conductance, hence lower the “self-gain” (gₘR_{DS}) of the device. This may also be undesirable, though perhaps not to the same degree as in digital applications. Non-linearity is also a concern, which DIBL contributes to as well. Excessive harmonic distortion can waste power, and reduce signal integrity.

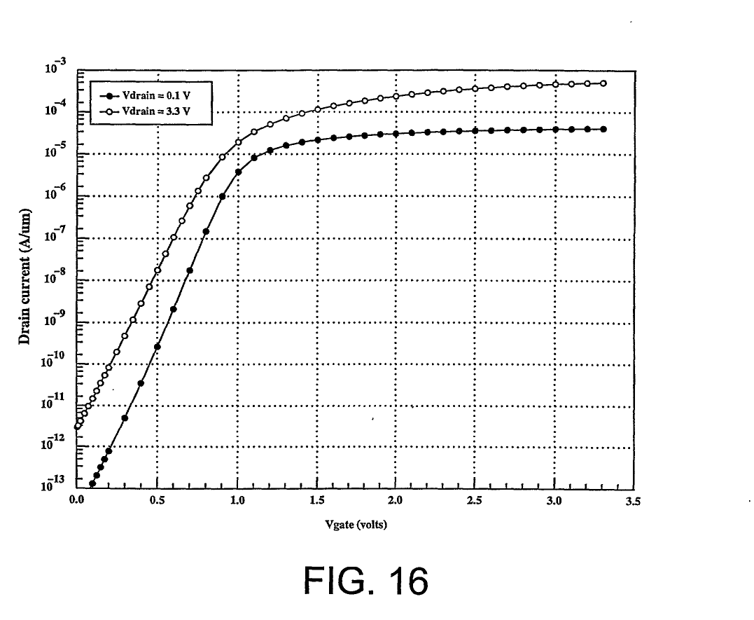

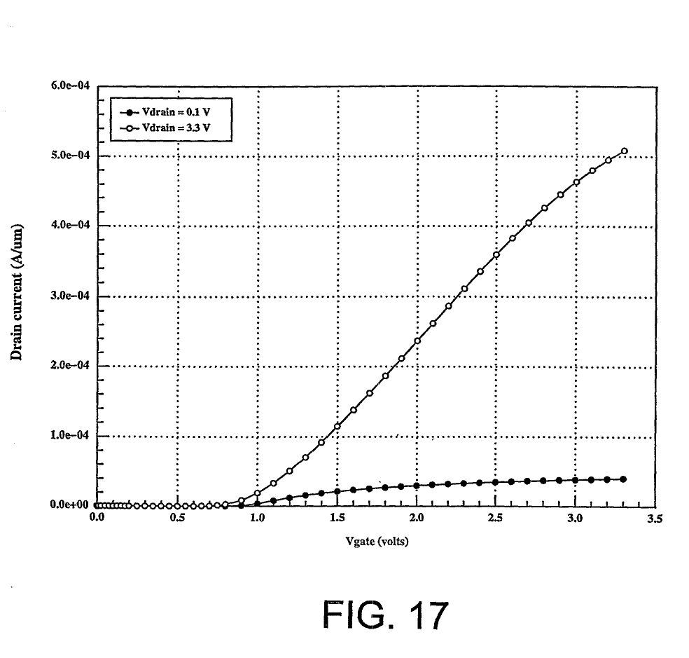

FIG. 16 shows the I_{DS}-V_{GS} curves for drain voltages of 0.1 V and 3.3 V on a semi-log scale. It can be seen that the sub-threshold characteristics remain fairly linear down to V_{GS}=0.0 V. Though the DIBL is somewhat higher than might be desired, it remains relatively constant throughout the sub-threshold region. FIG. 17 shows the same sweep on a linear scale. This Figure illustrates a high gate field roll-off in mobility for this device, that is not characteristic of conventional Fermi-FETs or MOSFETs.

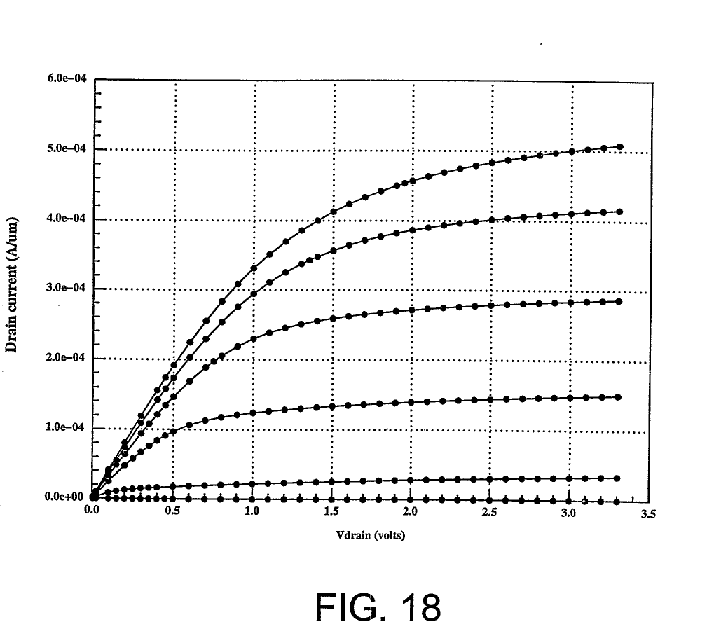

FIG. 18 shows the I_{DS}-V_{DS} curves for gate voltages from 0.0 to 3.3 volts in steps of 0.55 volts. The oxide thickness is 110 Å. Again, the high gate field mobility degradation is shown for the V_{GS}=V_{DD} sweep. This appears to be due to the increased total RDS resistance because of the fixed, gate-independent resistance of the drift region implant. The resistivity of the drift region implant begins to dominate the total source-drain resistance RDS relative to the gate-controlled channel resistance. Indeed, providing better coupling from the gate to the channel appears to provide increasingly little additional reduction in channel resistance.

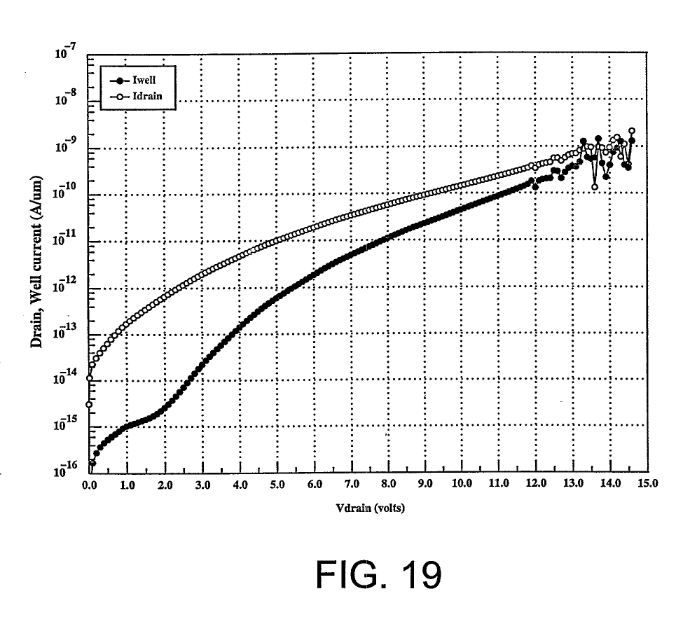

FIG. 19 illustrates semi-logarithmic I_{DS}-V_{DS} and I_{well}-V_{DS} characteristics for gate bias of 0.0 V. The oxide thickness is 110 Å. The onset of impact ionization can be seen at high V_{DS} as the drain voltage approaches 15.0 volts.

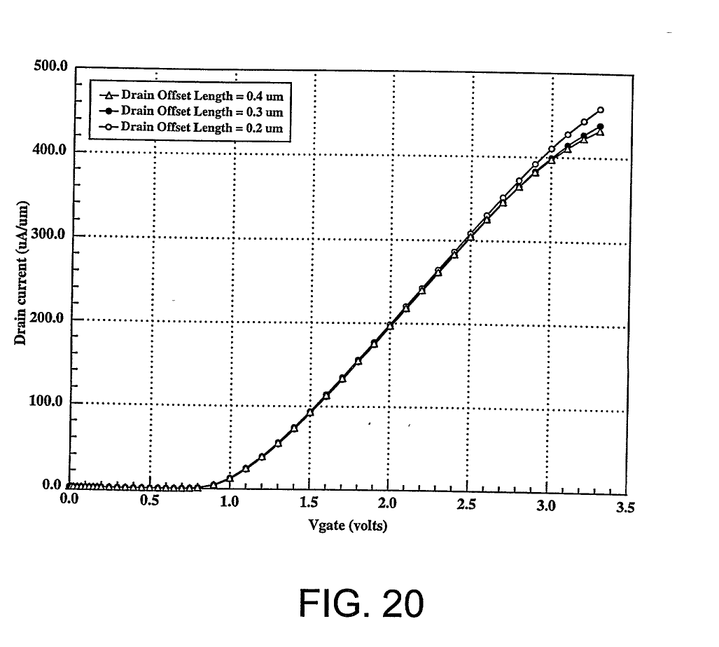

In FIG. 20, the drift region (drain offset) length is varied from 0.20 μm to 0.30 μm to 0.40 μm. Drain bias is set to 3.3V. For these simulations, a slightly lower channel implant is used (5.0×10¹¹) and no energy-balance model is in effect, so the currents are somewhat lower than reported in Table 3. As the gate voltage is increased towards V_{DD}, the effect of the drift region implant is seen. The L_{D}=0.20 μm curve shows the best current and most linear transconductance. As L_{D} approaches zero in the limit, the device would show a nearly constant gₘ with V_{GS}, as with a conventional Fermi-FET or MOSFET.

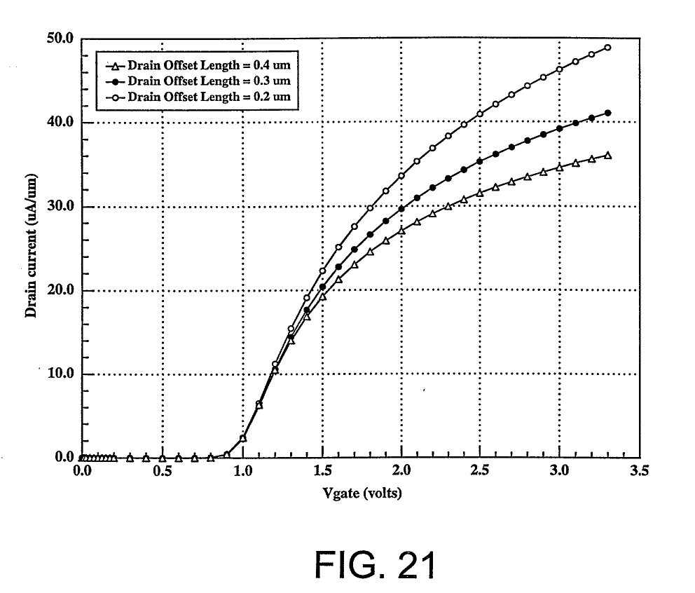

FIG. 21 shows the same effect with a low drain bias of 0.1 V. Here the effect of the drift region resistance is spread over the entire gate voltage range, resulting in the wide separation in characteristics. There is no breakpoint where the drift region resistance begins to dominate. Rather, the R_{DS} is reduced over the entire gate voltage range.

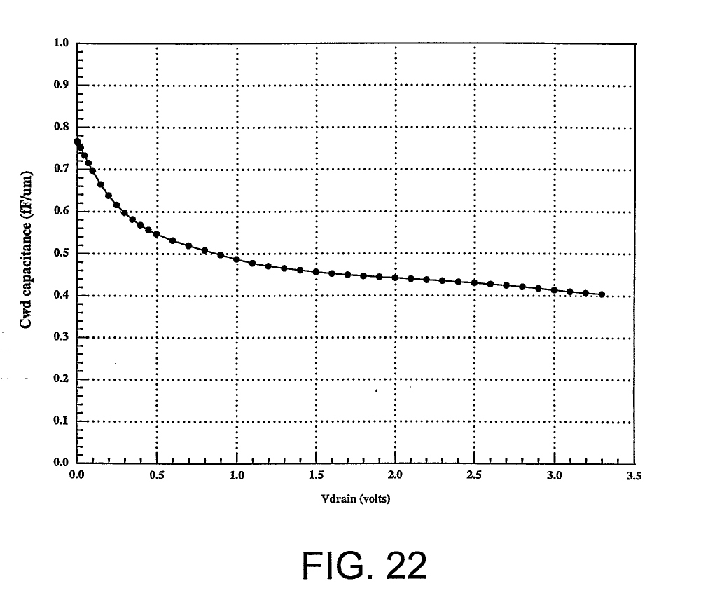

Small-signal conductance and capacitance simulation results will now be described. FIG. 22 shows the source/drain junction capacitance at zero volts gate bias, as the drain bias is swept from 0 to 1.8 volts. From previous work, this capacitance is typically from 30% to 50% less than an equivalent MOSFET.

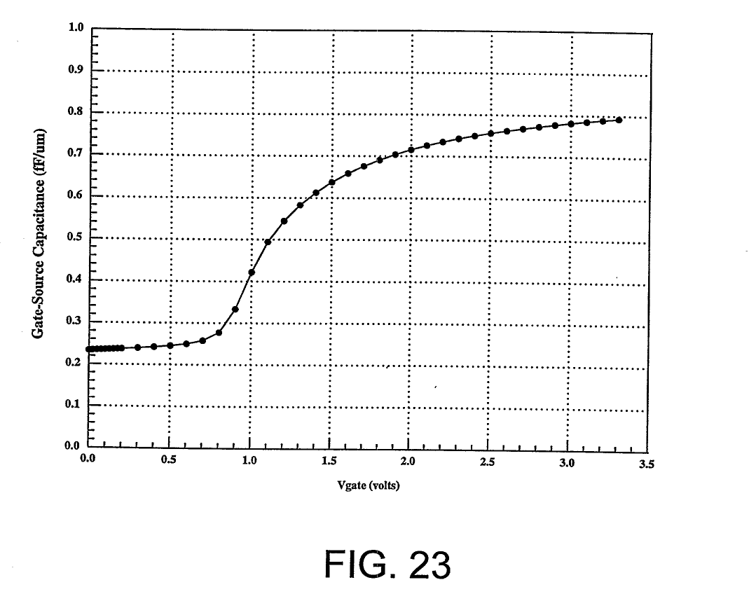

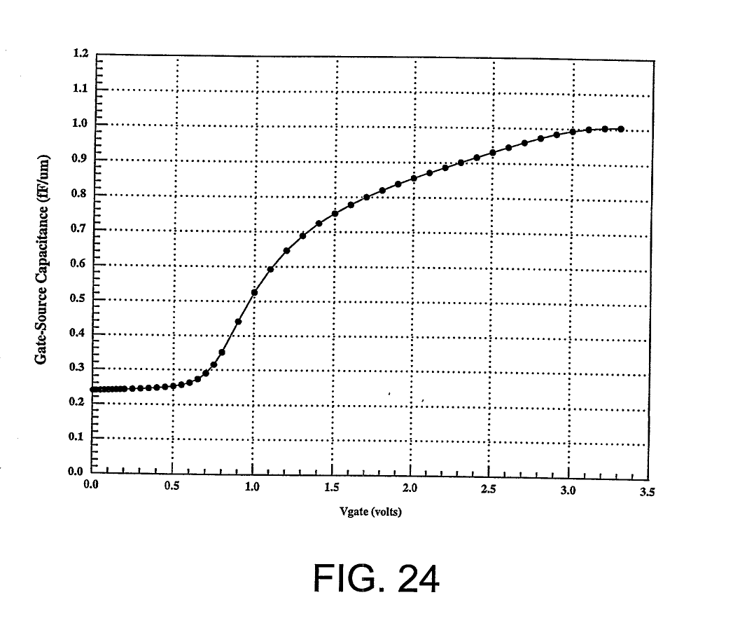

FIGS. 23 and 24 show the gate-to-source capacitance with the drain bias set to 0.1V and 3.3V, respectively. These curves saturate at close to COX, the oxide capacitance, as with a conventional MOSFET. Since the Fermi-FET is an accumulation rather than an inversion device, and the dopings may be lower, the CV curves at low gate voltages usually fall below those of conventional MOSFETs.

One feature of a Fermi-FET is the transconductance (gₘ) as the device turns on. The shape of this curve is usually dramatically different when compared with conventional CMOS devices, particularly with inversion surface-channel devices. It is not unusual to see peaks in the gₘ that are 2 to 3 times in magnitude higher than conventional surface or buried-channel devices. The maximum gₘ differential occurs just above V_{TH} in the linear region of operation.

An explanation for this difference will now be described. Consider the case of a low drain field with the channel forming either exactly at or somewhat below the surface. At the point where the channel forms, the vertical field throughout the channel region is much smaller than in conventional devices. In fact, it is preferably exactly zero at the point of channel formation. Once this point is reached, a large carrier distribution forms, moving at a high velocity due to the reduced vertical field and resulting higher mobility. The total charge in the channel at this point is much more than that at the surface of a conventional surface or buried-channel MOSFET. As the gate voltage continues to increase beyond V_{TH} to V_{FB}+V_{b1}, surface conduction begins via an accumulation layer. The accumulation layer contributes most of the mobile carriers contributing to current flow in saturation. Velocity saturation occurs as in conventional surface-channel devices, which accounts for a roll-off in the gₘ, but the Ferni-FET gₘ remains significantly higher, compared to a MOSFET, into saturation. The large peak of twice a MOSFET's gₘ reduces to about 1.3 times that of a MOSFET at high gate voltages.

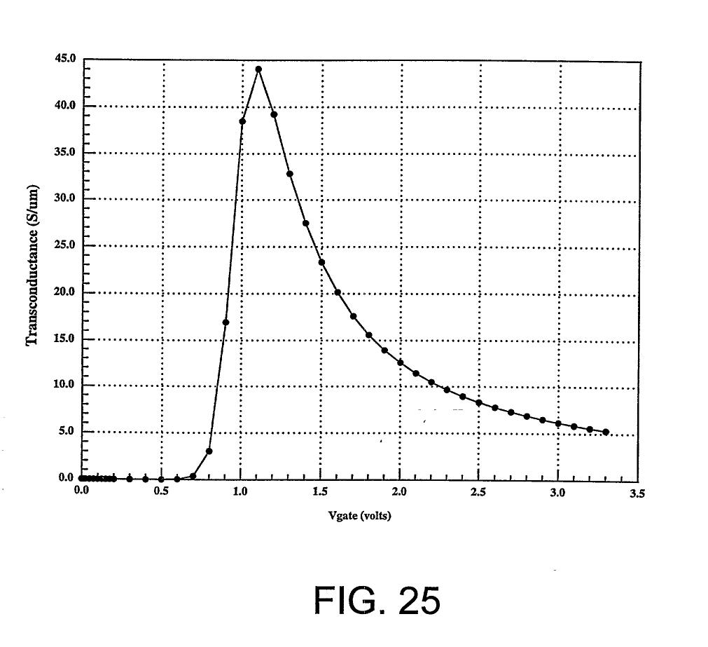

FIG. 25 shows the gₘ versus gate voltage characteristic at a low drain field with the drain bias set to 0.1V and a device with W=1.0 μm. The gₘ peaking is clearly seen. This behavior has been repeatedly simulated and measured on silicon for a variety of device geometries and process flows and may be a distinguishing electrical characteristic of the Fermi-FET. It is usually at least twice the gₘ of an equivalent MOSFET. The gₘ rolls off due to velocity saturation and follows the same shape as a MOSFET curve, but maintains a 20% to 30% advantage over the MOSFET up to V_{DS}=V_{DD}.

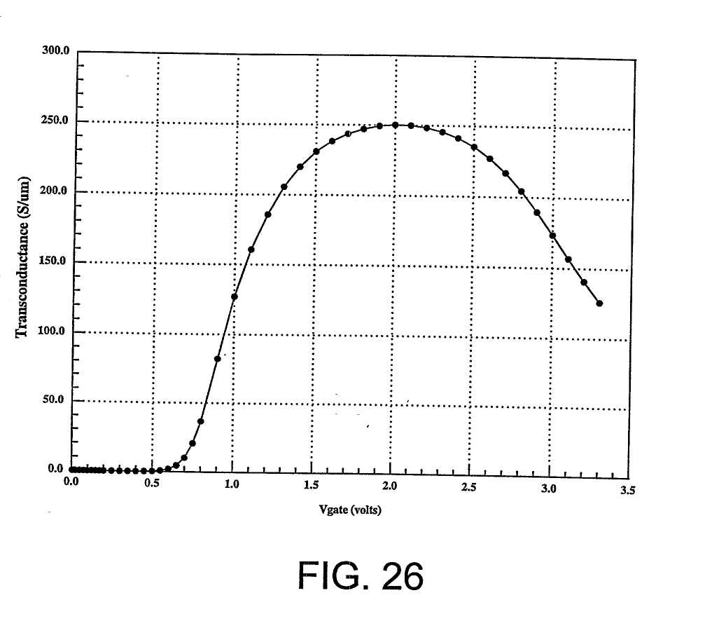

FIG. 26 is a plot of the gₘ versus gate voltage curve at a drain bias of 3.3V. Here, the shape of the curve is grossly different from either a conventional Fermi-FET or a MOSFET due to the previously discussed effect of the drift region resistance. The reduction in gₘ is clear above the mid-supply voltage. For a conventional Fermi-FET or MOSFET, the gₘ curve would flatten out and remain relatively constant as V_{GS} is increased up to V_{DD}.

Accordingly, offset drain Fermi-FETs can exceed the performance of conventional surface-channel designs. An offset drain Fermi-FET can provide higher I_{DSAT} current and higher linear and saturation gₘ at lower leakage and slightly higher threshold voltage than conventional MOSFETs. An offset drain Fermi-FET can provide significantly lower junction capacitance and slightly lower effective gate capacitance than conventional surface-channel MOSFETs. Fermi-FETs have a large peak in the gₘ just above threshold due to the nature of the turn-on characteristics. This peak may be a distinguishing characteristic of the Fermi-FET and has been both simulated and measured. The value of this peak is typically more than twice the gₘ of a conventional surface-channel MOSFET. Both the triode and saturated gₘ values exceed those of MOSFETs due to the higher mobility enjoyed by the LD Fermi-FET.

Other properties including hot-electron degradation, thermal sensitivities, matching properties and other analog characteristics also may be better than those for equivalent MOSFETs. Additional improvements may also be obtained when conventional offset drain features, including but not limited to field plates and lightly doped drains, are used with offset drain Fermi-FETs according to the present invention.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed:

1. A Fermi-threshold field effect transistor (Fermi-FET) comprising:
spaced apart source and drain regions in an integrated circuit substrate;
a Fermi-FET channel in the integrated circuit substrate, between the spaced apart source and drain regions;
a gate insulating layer on the integrated circuit substrate, between the spaced apart source and drain regions; and
a gate electrode on the gate insulating layer, wherein the gate electrode is closer to the source region than to the drain region.

2. A Fermi-FET according to claim 1 further comprising:
a Fermi-FET tub in the integrated circuit substrate, beneath the Fermi-FET channel.

3. A Fermi-FET according to claim 1 wherein the gate electrode comprises a metal gate electrode.

4. A Fermi-FET according to claim 1 wherein the gate electrode comprises a polysilicon gate electrode.

5. A Fermi-FET according to claim 1 further comprising a drift region in the integrated circuit substrate, between the drain region and the Fermi-FET channel.

6. A Fermi-FET according to claim 5 wherein the draft region is doped same conductivity type as the drain region, at lower doping concentration.

7. A Fermi-threshold field effect transistor (Fermi-FET) comprising:
spaced apart source and drain regions in an integrated circuit substrate;
a Fermi-FET channel in the integrated circuit substrate, between the spaced apart source and drain regions;
a gate insulating layer on the integrated circuit substrate, between the spaced apart source and drain regions; and
a gate electrode on the gate insulating layer, wherein the drain region is spaced farther away from the gate electrode than the source region.

8. A Fermi-FET according to claim 7 further comprising:
a Fermi-FET tub in the integrated circuit substrate, beneath the Fermi-FET channel.

9. A Fermi-FET according to claim 7 wherein the gate electrode comprises a metal gate electrode.

10. A Fermi-FET according to claim 7 wherein the gate electrode comprises a polysilicon gate electrode.

11. A Fermi-FET according to claim 7 further comprising a drift region in the integrated circuit substrate, between the drain region and the Fermi-FET channel.

12. A Fermi-FET according to claim 11 wherein the drift region is doped same conductivity type as the drain region, at lower doping concentration.

13. A Fermi-threshold field effect transistor (Fermi-FET) comprising:
a Fermi-FET channel in an integrated circuit substrate;
a gate insulating layer on the integrated circuit substrate, adjacent the Fermi-FET channel;
a gate electrode on the gate insulating layer opposite the Fermi-FET channel, the gate electrode including opposing first and second ends;
a source region in the integrated circuit substrate adjacent the first end of the gate electrode; and
a drain region in the integrated circuit substrate and laterally spaced apart from the second end of the gate electrode.

14. A Fermi-FET according to claim 13 further comprising:
a Fermi-FET tub in the integrated circuit substrate, beneath the Fermi-FET channel.

15. A Fermi-FET according to claim 13 wherein the gate electrode comprises a metal gate electrode.

16. A Fermi-FET according to claim 13 wherein the gate electrode comprises a polysilicon gate electrode.

17. A Fermi-FET according to claim 13 further comprising a drift region in the integrated circuit substrate, between the drain region and the Fermi-FET channel.

18. A Fermi-FET according to claim 17 wherein the drift region is doped same conductivity type as the drain region, at lower doping concentration.

19. A Fermi-FET according to claim 13 wherein the source region is laterally spaced apart from the first end of the gate electrode by a first distance and wherein the drain region is laterally spaced apart from the second end of the gate electrode by a second distance that is greater than the first distance.

20. An offset drain Fermi-threshold field effect transistor (Fermi-FET).
